(19) United States
(12) Patent Application Publication
(10) Pub. No.: US 2025/0126957 A1
(43) Pub. Date: Apr. 17, 2025

(54) STRESS-FREE PEROVSKITE LAYERS AND METHODS OF MAKING THE SAME

(71) Applicant: Alliance for Sustainable Energy, LLC, Golden, CO (US)

(72) Inventors: Min CHEN, Lakewood, CO (US); Joseph Matthew LUTHER, Boulder, CO (US)

(21) Appl. No.: 18/917,349

(22) Filed: Oct. 16, 2024

Related U.S. Application Data
(60) Provisional application No. 63/590,610, filed on Oct. 16, 2023.

(51) Int. Cl. H10K 30/40; H10K 30/50; H10K 71/15

(52) U.S. Cl. CPC H10K 30/40; H10K 30/50; H10K 71/15

(57) ABSTRACT

The present disclosure relates to a device that includes a first layer that includes a perovskite, the first layer having a thickness (t), and an additive that includes at least one of an aromatic ammonium cation and/or an alkyl ammonium cation, wherein the perovskite has a plurality of perovskite grains separated by a plurality of grain boundaries, a portion of the additive is positioned at or near the grain boundaries or at a surface of the first layer or a combination thereof, and the first layer is characterized by a stress between −50 MPa and 50 MPa.

### CROSS-REFERENCE TO RELATED APPLICATIONS

This application claims priority from U.S. Provisional Patent Application No. 63/590,610 filed on Oct. 16, 2023, the contents of which are incorporated herein by reference in their entirety.

### CONTRACTUAL ORIGIN

This invention was made with government support under Contract No. DE-AC36-08GO28308 awarded by the Department of Energy and Agreement No. IAG-22-23130 awarded by the Department of Defense. The government has certain rights in the invention.

### BACKGROUND

The mechanical reliability of perovskite solar cells (PSCs) suffers from the low facture energy in perovskite materials, low adhesion interfaces toughness in the layered PSCs devices, and the severe internal stress/strain in PSCs with mismatching coefficients of thermal expansion in the multiple layers, making them prone to driving fracture and premature delamination. Therefore, there remains a need for improved materials, compositions, and methods for economically and reliably manufacturing PSCs that minimize and/or eliminate these problems.

### SUMMARY

An aspect of the present disclosure is a device that includes a first layer that includes a perovskite, the first layer having a thickness (t), and an additive that includes at least one of an aromatic ammonium cation and/or an alkyl ammonium cation, wherein the perovskite has a plurality of perovskite grains separated by a plurality of grain boundaries, a portion of the additive is positioned at or near the grain boundaries or at a surface of the first layer or a combination thereof, and the first layer is characterized by a stress between −50 MPa and 50 MPa, as measured by x-ray diffraction (XRD) at room temperature. In some embodiments of the present disclosure, the additive may further include an anion.

In some embodiments of the present disclosure, the anion may include at least one of a halide, a pseudo halide, formate, carbonate, and/or nitrate. In some embodiments of the present disclosure, the additive may be positioned at or near the grain boundaries. In some embodiments of the present disclosure, the stress may be between −5 MPa and 5 MPa. In some embodiments of the present disclosure, the first layer may be further characterized by a strain of between −0.1 and 0.1 (unitless). In some embodiments of the present disclosure, the first layer may have a thickness between 100 nm and 20 μm.

In some embodiments of the present disclosure, the additive may have a length between 5 Å and 75 Å. In some embodiments of the present disclosure, the alkyl group of the alkyl ammonium cation may include a hydrocarbon group having between 2 and 30 carbon atoms. In some embodiments of the present disclosure, the alkyl ammonium cation may include n-octyl ammonium. In some embodiments of the present disclosure, the aromatic ammonium cation may include at least one of benzyl ammonium, methylbenzyl ammonium, or a combination thereof. In some embodiments of the present disclosure, the anion may include at least one of iodide, chloride, bromide, formate, carbonate, nitrate, thiocyanate, or a combination thereof. In some embodiments of the present disclosure, a portion of the additive may be positioned in the first layer at a concentration between greater than 0 mol % and 10 mol %.

In some embodiments of the present disclosure, the device may further include a second layer, where the first layer and the second layer are parallel and adjacent to each other, forming a first interface. In some embodiments of the present disclosure, a portion of the additive may be positioned at the first interface.

An aspect of the present disclosure is a method that includes preparing a solution that includes a perovskite precursor and an additive, and applying the solution to a surface, creating a liquid layer of the solution, where the applying results in the forming of a solid perovskite layer having a plurality of grains and grain boundaries, the perovskite layer forms an interface between the surface and the perovskite layer, and a portion of the additive is positioned within a grain boundary, at the interface, or a combination thereof.

In some embodiments of the present disclosure, the solution may include an A-site component (A), a B-site component (B), and an X-site component (X) for synthesizing a target perovskite crystal that includes A, B, and X, and the solution may include the additive at a molar concentration between greater than 0 mol % and less than 10 mol %, where the molar concentration is calculated relative to the moles of B added to the solution. In some embodiments of the present disclosure, the molar concentration may be between 1 mol % and 5 mol %, inclusively. In some embodiments of the present disclosure, the applying may be performed using at least one of spin-coating, blade-coating, curtain-coating, spray-coating, or a combination thereof. In some embodiments of the present disclosure, the solution may further include a first solvent.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates (Panel A) a device having a perovskite layer and (Panel B) a surface in the xz-plane of a perovskite layer, according to some embodiments of the present disclosure.

FIGS. 2A and 2B illustrate a perovskite in a corner-sharing, cubic phase arrangement, according to some embodiments of the present disclosure. This figure is not intended to be limited to cubic phase structures. Other structures fall within the scope of the present disclosure, for example, tetragonal and/or orthorhombic.

FIG. 3A illustrates three possible corner-sharing phases for perovskites, (Panel A) a cubic phase (i.e., α-ABX3), (Panel B) a tetragonal crystalline phase (i.e., β-ABX3), and (Panel C) an orthorhombic crystalline phase (i.e., γ-ABX3), according to some embodiments of the present disclosure.

FIG. 3B illustrates a perovskite in one of the three possible phases, the cubic phase (i.e., α-phase), compared to two non-perovskite phases (i.e., non-corner sharing), according to some embodiments of the present disclosure.

FIG. 4 illustrates 2D, 1D, and 0D perovskite-like structures, in Panels A, B, and C, respectively, according to some embodiments of the present disclosure.

FIG. 5A illustrates (Panel A) XRD patterns of perovskite layers with molar ratios of 0, 1%, 2%, 4% of n-octyl ammonium iodide (OAI), designated as OAI-0, OAI-1, OAI-2 and OAI-4 respectively and (Panel B) a schematic of the XRD sin² ψ method for quantifying the residual stress, according to some embodiments of the present disclosure.

FIG. 5B illustrates (Panel A) XRD patterns at different tilt angles for the OAI-1 perovskite layers, according to some embodiments of the present disclosure. Higher values of ψ are shown in lighter colored lines. Panel B illustrates XRD patterns at different tilt angles for the OAI-0 perovskite layers, according to some embodiments of the present disclosure.

FIG. 5C illustrates (Panel A) XRD d₂₂₀ versus sin² ψ plots for the OAI-0 and OAI-1 perovskite layers and (Panel B) a comparison of the residual stress at room temperature in the OAI-0, OAI-1, OAI-2 and OAI-4 perovskite layers, according to some embodiments of the present disclosure.

FIG. 5D illustrates top-view SEM images for (Panel A) OAI-0 and (Panel B) OAI-1 perovskite layers, according to some embodiments of the present disclosure. (inset, cross-sectional SEM image of the corresponding perovskite layer).

FIG. 6 illustrates TOF-SIMS maps for (Panel A) OAI-1 and (Panel B) OAI-4 perovskite layers at depths of 200 nm and 400 nm (left and right, respectively), according to some embodiments of the present disclosure.

FIGS. 7A-7D illustrate aspects of the present disclosure, according to some embodiments of the present disclosure: Panel A of each of FIGS. 7A-7D illustrate schematics (not to scale) of planar perovskite solar cells (PSCs) or planar perovskite solar modules (PSMs) tested. FIGS. 7A and 7B correspond to n-i-p regular planar PSCs and perovskite solar modules (PSMs), respectively. FIGS. 7C and 7D correspond to p-i-n inverse planar PSCs and PSMs, respectively. Panel B of each of FIGS. 7A-7D illustrate J-V responses, in reverse and forward scans for the corresponding PSCs or PSMs illustrated in Panel A of FIGS. 7A-7D. Panel C of each of FIGS. 7A-7D illustrate stable output for the corresponding PSCs or PSMS illustrated in Panel A of FIGS. 7A-7D.

FIG. 8 illustrates external quantum efficiency (EQE) spectra of a best-performing n-i-p PSC based on OAI-1, according to some embodiments of the present disclosure.

FIG. 9 illustrates statistics for the PV performance parameters J_{SC}, V_{OC}, fill factor (FF), and PCE for (Panel A) n-i-p PSCs, (Panel B) n-i-p PSMs, (Panel C) p-i-n PSCs, and (Panel D) p-i-n PSMs (20 cells or modules of each type), all based on OAI-1, according to some embodiments of the present disclosure.

FIGS. 10A-10G illustrate aspects of the present disclosure, according to some embodiments of the present disclosure: The evolution of power conversion efficiency (PCE) of n-i-p PSCs (Panel A of FIG. 10A), n-i-p PSMs (Panel B of FIG. 10A), p-i-n PSCs (Panel A of FIG. 10B), and p-i-n PSMs (Panel B of FIG. 10B) over 500 temperature cycles between −40° C. and 85° C., 6 hours per cycle. Typical JV curves (reverse scan) after 100 cycles in n-i-p PSCs (Panel A of FIG. 10C) and n-i-p PSMs (Panel B of FIG. 10C), in p-i-n PSCs (Panel A of FIG. 10D), and p-i-n PSMs (Panel B of FIG. 10D). The evolution of power conversion efficiency of n-i-p PSCs (Panel A of FIG. 10E) and p-i-n PSCs (Panel B of FIG. 10E) over 5000 temperature cycles between −40° C. and 85° C., 6 minutes per cycle. Typical JV curves (reverse scan) after 2500 cycles in n-i-p PSCs (Panel A of FIG. 10F), and in p-i-n PSCs (Panel B of FIG. 10F). FIG. 10G illustrates PCE of a champion p-i-n solar cells based on OAI-1, according to some embodiments of the present disclosure.

FIGS. 11A-11E illustrate aspects of the present disclosure, according to some embodiments of the present disclosure: FIG. 11A illustrates cross-sectional SEM images of as-fabricated PSCs (Panel A) with OAI-0 and (Panel B) with OAI-1 after thermal cycling. TA spectra at various post-pump delay times of PSCs (FIG. 11B) with OAI-0 and (FIG. 11C) with OAI-1 after thermal cycling. The pump excitation energy is 3.1 eV (400 nm) incident from SnO₂/perovskite interface. FIG. 11D illustrates a TA kinetics summary for of PSCs (FIG. 11B) with OAI-0 and (FIG. 11C) with OAI-1 after thermal cycling. Solid line: before thermal cycling. Dot line: after thermal cycling. FIG. 11E illustrates interfacial toughness data, before and after thermal cycling for samples OAI-0 and OAI-1.

FIG. 12 illustrates the evolution of XRD peaks of perovskite layers in device stacks during thermal cycling for samples OAI-0 (Panel A) and OAI-1 (Panel B), according to some embodiments of the present disclosure.

FIGS. 13A and 13B illustrate TA spectroscopy for PSCs based on OAI-0 (FIG. 13A) and OAI-1 (FIG. 13B) before thermal cycling, according to some embodiments of the present disclosure.

FIGS. 14A-14C illustrate TA spectroscopy for pure perovskite samples based on OAI-0 and OAI-1 after thermal cycling, according to some embodiments of the present disclosure.

FIG. 15 illustrates SEM images of the fractured buried interface of the perovskite layers before and after thermal cycling, according to some embodiments of the present disclosure.

### REFERENCE NUMERALS

100 device
110 first layer
120 second layer
130 third layer
140 first interface
150 second interface
160 grain
170 grain boundary
200 perovskite
210 A-cation
220 B-cation
230 X-anion

### DETAILED DESCRIPTION

The present disclosure relates to methods and materials that, among other things, reduce and/or eliminate the residual stresses present in perovskite layers after thermal annealing. In some embodiments of the present disclosure, this is achieved by incorporating molecules having long alkyl chains into the perovskite layers. In some embodiments of the present disclosure, these molecules may be present at and/or in the grain boundaries that separate individual perovskite grains from neighboring grains. In some embodiments of the present disclosure, these molecules may be present at the surfaces of a perovskite layer, for example, at the interfaces formed between the perovskite layer and neighboring adjacent layers, such as charge transport layers. The presence of the relatively large sized alkyl chains, e.g., between 5 Å and 75 Å or between 15 Å and 25 Å in length, may result in their preferential location at the grain boundaries and interfaces during the formation of perovskite layers, thereby relieving the residual internal stresses typically present in final (e.g., after annealing) perovskite layers at room temperature (RT; e.g., between 15° and 25° C.). As shown herein, this method not only increases the power conversion efficiency (PCE) of perovskite solar cells (PSCs) and the PCE of perovskite solar modules (PSMs), but also improves thermal cycling lifetime of both PSCs and PSMs (n80 under IEC 61215:2016 qualification of 500 cycles for PSCs and 200 cycles for PSMs).

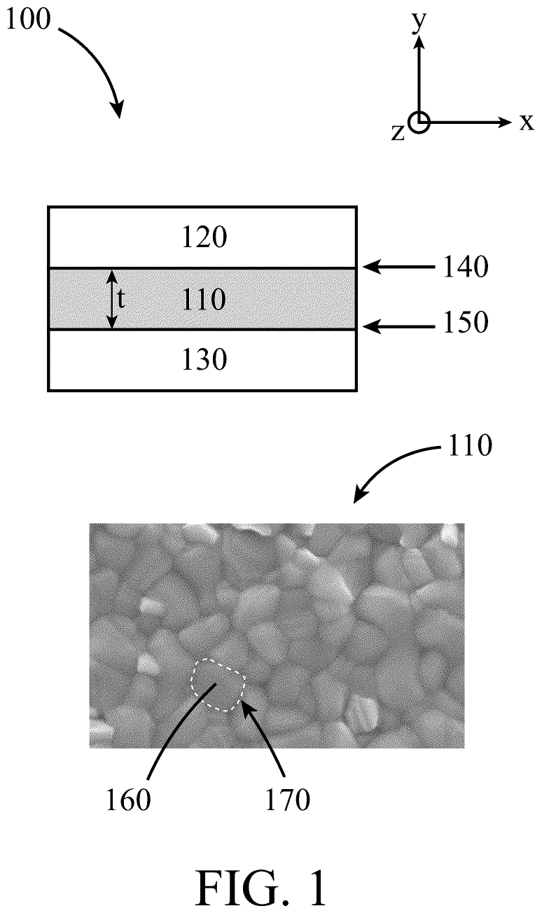

Panel A of FIG. 1 illustrates a device 100, e.g., a PSC, according to some embodiments of the present disclosure. This exemplary device 100 includes a first layer 110 positioned between a second layer 120 and a third layer 130. The first layer 110 includes a perovskite and is also referred to herein as a perovskite layer. Panel B of FIG. 1 illustrates a scanning electron microscopy (SEM) image of a surface in the xz-plane of a perovskite layer. This image shows that a perovskite layer may be composed of a plurality of perovskite crystals, i.e., grains 160, where the individual grains 160 are separated from neighboring grains by grain boundaries 170, where the grain boundaries 170 result from the crystallization process and may be single and/or polycrystalline structures themselves. In some embodiments of the present disclosure, a second layer 120 and a third layer 130 may be a first charge transport layer (CTL) and a second CTL, respectively.

In some embodiments of the present disclosure, an HTL may be constructed using at least one of NiOₓ (0≤x≤2), 2,2′,7,7′-tetrakis[N,N-di(4-methoxyphenyl)amino]-9,9′-spirobifluorene (Spiro-OMeTAD), poly[bis(4-phenyl)(2,4,6-trimethylphenyl)amine (PTAA), poly(3,4-ethylenedioxythiophene) polystyrene sulfonate (PEDOT:PSS), and/or carbazole self-assembled molecules. In some embodiments of the present disclosure, an ETL may be constructed using at least one of SnOₓ, TiO₂, a fullerene (e.g., C60), a fullerene derivative (e.g., [6,6]-phenyl C61 butyric acid methyl ester (PCBM)), and/or indium tin oxide. Depending on whether the device 100 is a p-i-n device or a n-i-p device, the order of the first CTL and second CTL will be reversed, with one being a hole-transport layer (HTL) and the other being an electron-transport layer (ETL). The plane at which the first layer 110 contacts the second layer 120 forms a first interface 140. Similarly, the plane at which the first layer 110 contacts the third layer 130 forms a second interface 150.

Referring again to FIG. 1, a first layer 110, i.e., a perovskite layer, may have a thickness, t (in the y-axis direction), between 100 nm and 20 μm or between 300 nm and 2 μm. As described above, molecules having long alkyl chains may be positioned within the first layer 110, for example at grain boundaries 150 and/or at the interfaces (140 and 150) formed by the first layer 110 with its neighboring layers, the second layer 120 and the third layer 130, respectively.

In some embodiments of the present disclosure, molecules having long alkyl chains may include an alkyl ammonium cation that is charge balanced with an anion. Examples, of anions include at least one of a halide, a pseudo halide, formate, carbonate, and/or nitrate. Examples of suitable halides include at least one of chloride, bromide, and/or iodide. An example of a pseudo halide is thiocyanate. As shown herein, the presence of an alkyl ammonium cation and/or an anion at grain boundaries 170 and/or interfaces (140 and/or 150) may reduce the stresses present within the first layer 110, i.e., the perovskite layer, to between 0 MPa and 20 MPa or between 0 MPa and 1 MPa, as measured by x-ray diffraction (XRD) at room temperature. In some embodiments of the present disclosure, a device 100 that includes molecules having long alkyl chains in the perovskite layer may be further characterized by a strain of about zero (strain is a unitless fractional value), where strain is a measure of the deformation of a material under the influence of an external force defined by,

$$ε = ( L - L 0 ) / L 0$$

where strain (ε) is the fractional change in length, L is the length after the external force is applied to the material and L0 is the original length of the material.

As one of ordinary skill in the art will recognize, and as described in more detail below, perovskite crystals can contain an alkyl ammonium cation charge balanced with a halide, where the alkyl ammonium cation is in the A-site position and the halide is in the X-anion position of a perovskite crystal having the exemplary composition of ABX3, where B refers to a B-site cation, typically, lead or tin. Thus, the additives described herein, e.g., alkyl ammonium and/or alkyl amine cations, in some embodiments, charge balanced with an anion, for reducing strain and/or stress in a final perovskite composition are not necessarily incorporated into the crystal structure of the perovskite making up a first layer 110. Instead, as described above, these the additives (cations and/or anions) may be present at the surfaces of a perovskite layer, for example, at the interfaces formed between the perovskite layer and neighboring adjacent layers, such as charge transport layers. They are not necessarily present in the bulk of a perovskite layer (i.e., first layer 110), the mass between the two interfaces (140 and 150). To distinguish the difference between molecules incorporated into the bulk of the perovskite layer from molecules added to reduce/eliminate stress and/or strain in the perovskite layer, the alkyl ammonium cations and charge-balancing anions, are referred to herein collectively as additives, additive molecules, additive alkyl ammonium cations, additive alkyl amines, and/or additive charge-balancing anions.

A variety of additive molecules having long alkyl chains may be utilized to reduce or eliminate the stresses present in the first layer 110. In some embodiments of the present disclosure, the alkyl group of an additive alkyl ammonium cation may include a hydrocarbon group having between 2 and 30 carbon atoms or between 6 and 10 carbon atoms. Such a hydrocarbon group may be a straight-chained hydrocarbon or a branched hydrocarbon. In some embodiments of the present disclosure, an alkyl group, i.e., hydrocarbon chain (straight or branched), may include other elements in addition to hydrogen and carbon. For example, an additive molecule utilized to reduce or eliminate the stresses present in a final perovskite layer (e.g., after annealing) may have long hydrocarbon chains (e.g., between 2 and 30 carbons) that also include at least one of nitrogen, sulfur, and/or phosphorus. In some embodiments of the present disclosure, a carboxylic acid may provide the same benefits to a device as described herein for additive alkyl ammonium cations. For example, n-octanoic acid may be included as an additive in a perovskite layer to relieve stresses. Thus, in some embodiments of the present disclosure, an additive may include a deprotonated carboxylic acid (a carboxylate; e.g., n-octyl carboxylate).

In some embodiments of the present disclosure, an additive alkyl ammonium cation may include at least one of n-butyl ammonium, n-pentyl ammonium, n-hexyl ammonium, n-heptyl ammonium, n-octyl ammonium, n-nonyl ammonium, n-decyl ammonium, up to alkyl groups having up to 12 carbon atoms (i.e., n-dodecyl ammonium) or up to 18 carbon atoms (i.e., n-oleyl ammonium). In some embodiments of the present disclosure, an additive alkyl ammonium charge balanced with an additive anion may be present in a first layer 110 at a concentration between greater than 0 mol % and 10 mol % or between greater than 0 mol % and 4 mol %, inclusively.

In some embodiments of the present disclosure, an alkylamine may be used as an additive in place of or in addition to an additive alkyl ammonium cation charge balanced with an additive anion. For example, in some embodiments of the present disclosure, n-octylamine may be used as an additive in place of or in addition to n-octyl ammonium iodide. Similarly, any of the additive alkyl ammonium cation/anion combinations described herein may be replaced with an equivalent amine molecule, or supplemented with an equivalent amine molecule.

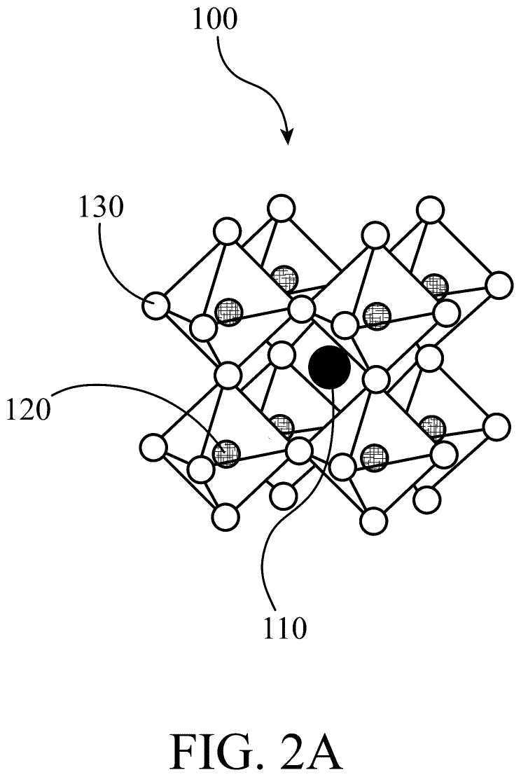

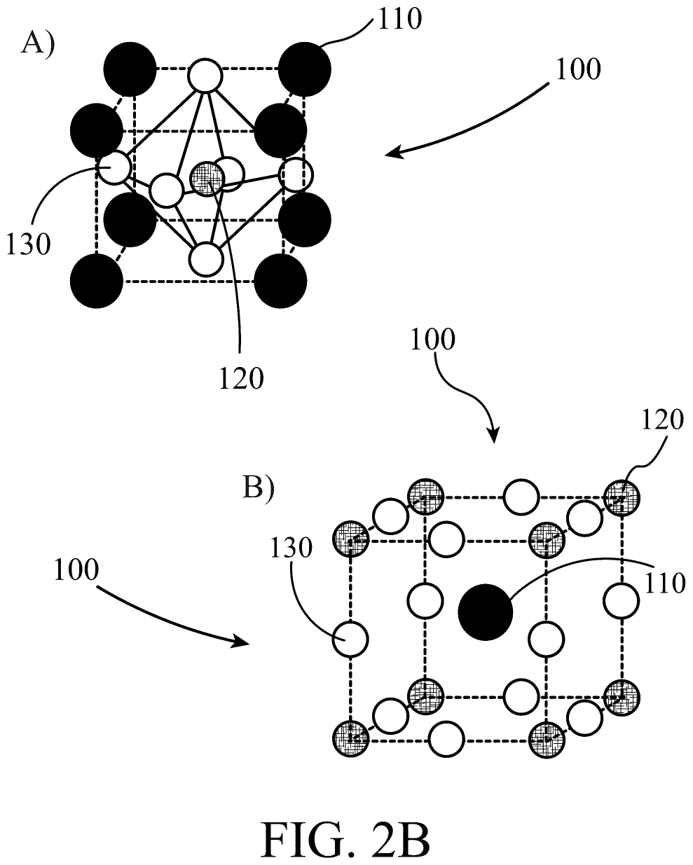

In general, the term “perovskite” refers to compositions having a network of corner-sharing BX₆ octahedra resulting in the general stoichiometry of ABX3. FIGS. 2A and 2B illustrate that perovskites 100, for example metal halide perovskites, may organize into a three-dimensional (3D) cubic crystalline structures (i.e., α-phase or α-ABX3) constructed of a plurality of corner-sharing BX₆ octahedra. In the general stoichiometry for a perovskite, ABX3, X (130) is an anion and A (110) and B (120) are cations, typically of different sizes. FIG. 2A illustrates that a perovskite 100 having an α-phase structure may be further characterized by eight BX₆ octahedra surrounding a central A-cation 110, where each octahedra is formed by six X-anions 130 surrounding a central B-cation 120 and each of the octahedra are linked together by “corner-sharing” of anions, X (130).

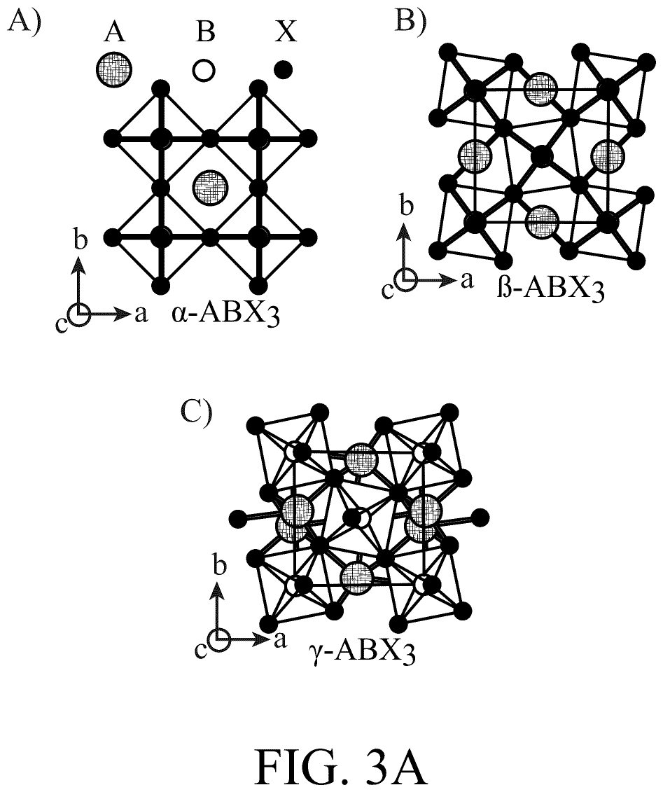

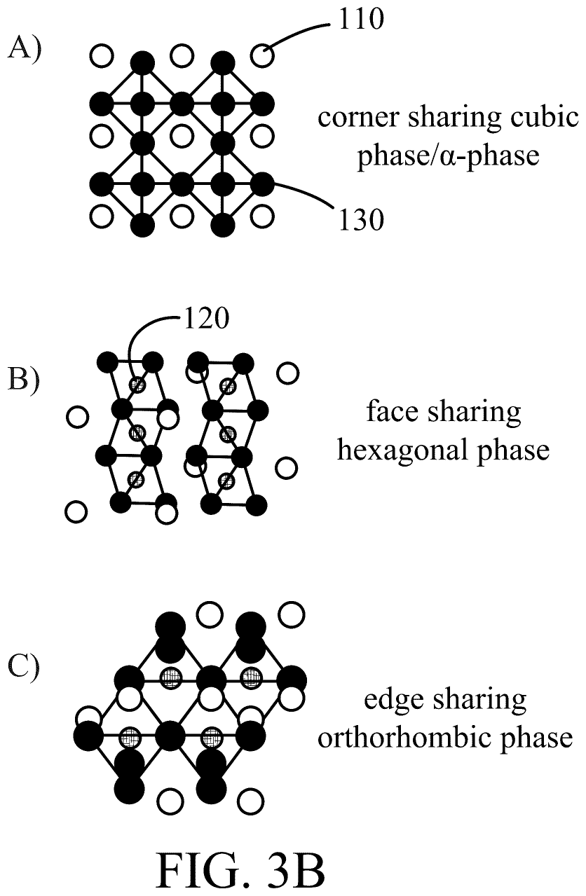

Panel A of FIG. 2B provides another visualization of a perovskite 100 in the α-phase, also referred to as the cubic phase. This is because, as shown in FIG. 2B, a perovskite in the α-phase may be visualized as a cubic unit cell, where the B-cation 120 is positioned at the center of the cube, an A-cation 110 is positioned at each corner of the cube, and an X-anion 130 is face-centered on each face of the cube. Panel B of FIG. 2B provides another visualization of the cubic unit cell of an α-phase perovskite, where the B-cation 120 resides at the eight corners of a cube, while the A-cation 110 is located at the center of the cube and with 12 X-anions 130 centrally located between B-cations 120 along each edge of the unit cell. For both unit cells illustrated in FIG. 2B, the A-cations 110, the B-cations 120, and the X-anions 130 balance to the general formula ABX3 of a perovskite, after accounting for the fractions of each atom shared with neighboring unit cells. For example, referring to Panel A of FIG. 2B, the single B-cation 120 atom is not shared with any of the neighboring unit cells. However, each of the six X-anions 130 is shared between two unit cells, and each of the eight A-cations 110 is shared between eight unit cells. So, for the unit cell shown in Panel A of FIG. 2B, the stoichiometry simplifies to B=1, A=8*0.125=1, and X=6*0.5=3, or ABX3. Similarly, referring again to Panel B of FIG. 2B, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8*0.125=1, and X=12*0.25=3, or ABX3. Referring again to Panel B of FIG. 2B, the X-anions 130 and the B-cations 120 of a perovskite in the α-phase are aligned along an axis; e.g., where the angle at the X-anion 130 between two neighboring B-cations 120 is exactly 180 degrees, referred to herein as the tilt angle. However, as shown in FIG. 3A, a perovskite 100 may assume other corner-sharing crystalline phases having tilt angles not equal to 180 degrees.

FIG. 3A illustrates that a perovskite can assume other crystalline forms while still maintaining the criteria of an ABX3 stoichiometry with neighboring BX₆ octahedra maintaining X anion (130) corner-sharing. Thus, in addition to α-ABX3 perovskites (in the cubic phase) having a tilt angle of 180 degrees, shown in Panel A of FIG. 3A, a perovskite may also assume a tetragonal crystalline phase (i.e., β-ABX3) (see Panel B of FIG. 3A) and/or an orthorhombic crystalline phase (i.e., γ-ABX3) (see Panel C of FIG. 3A), where the adjacent octahedra are tilted relative to the reference axes a, b, and c.

FIG. 3B illustrates that the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX3 stoichiometry. Referring to FIG. 3B, Panel A illustrates a perovskite in the cubic phase, i.e., α-ABX3, compared to a non-perovskite structure constructed of face-sharing BX₆ octahedra resulting in a hexagonal crystalline structure (see Panel B of FIG. 3B) and a non-perovskite structure constructed of edge-sharing BX₆ octahedra resulting in an orthorhombic crystalline structure (see Panel C of FIG. 3B).

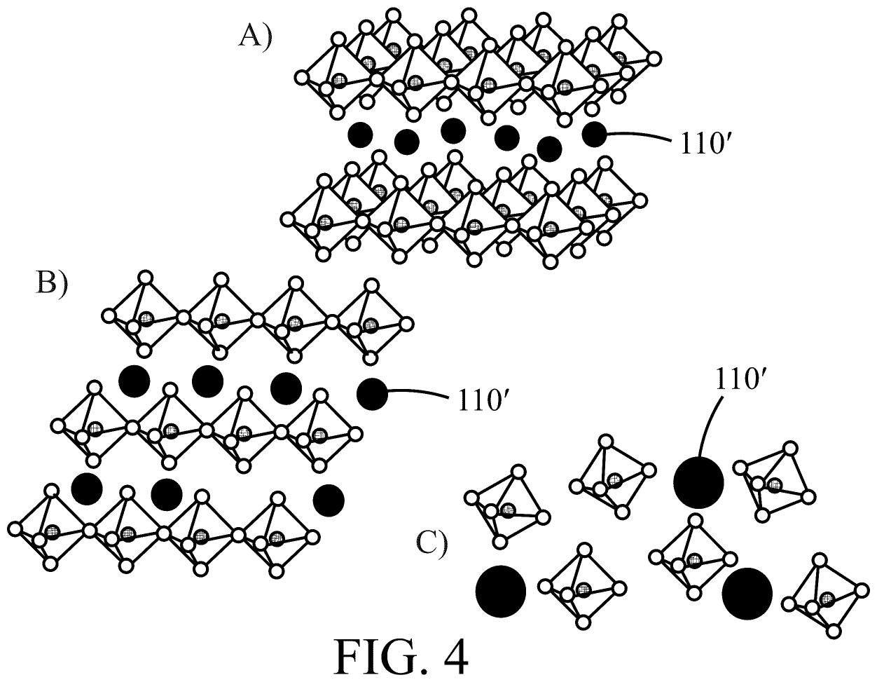

Further, referring now to FIG. 4, the elements used to construct a perovskite, as described above, A-cations 110, B-cations 120, and X-anions 130, may result in non-3D (i.e., lower dimensional structures) perovskite-like structures such as two-dimensional (2D) structures, one-dimensional (1D) structures, and/or zero-dimensional (0D) structures. As shown in FIG. 4, such lower dimensional, perovskite-like structures still include the BX₆ octahedra, and depending on the dimensionality, e.g., 2D or 1D, may still maintain a degree of X-anion corner-sharing. However, as shown in FIG. 4, the X-anion 130 corner-sharing connectivity of neighboring octahedra of such lower dimensional structures, i.e., 2D, 1D, and 0D, is disrupted by intervening A-cations 110. Such a disruption of the neighboring octahedra, can be achieved by, among other things, varying the size of the intervening A-cations 110.

Referring to Panel A of FIG. 4, a 3D perovskite may be transformed to a 2D perovskite-like structure, 1D perovskite-like structure, and/or 0D perovskite-like structure. Where the degree of X-anion 130 corner sharing decreases and the stoichiometry changes according to the formula (A′)ₘ(A)ₙ₋₁BₙX₃ₙ₊₁, where monovalent (m=2) or divalent (m=1) A′ cations 110′ can intercalate between the X-anions of 2D perovskite-like sheets. Referring to Panel C of FIG. 4, 1D perovskite-like structures are constructed by BX₆ octahedral chained segments spatially isolated from each other by surrounding bulky organic A′-cations 110′, leading to bulk assemblies of paralleled octahedral chains. Referring to Panel C of FIG. 4, typically, the 0D perovskite-like structures are constructed of isolated inorganic octahedral clusters and surrounded by small A′-cations 110′, which may be connected via hydrogen bonding. In general, as n approaches infinity the structure is a pure 3D perovskite and when n is equal to 1, the structure is a pure 2D perovskite-like structure. More specifically, when n is greater than 10 the structure is considered to be essentially a 3D perovskite material and when n is between 1 and 5, inclusively, the structure is considered substantially a 2D perovskite-like material.

For simplification, as used herein the term “perovskite” will refer to each of the structures illustrated in FIG. 2A through FIG. 4, unless specified otherwise. Thus, unless specified otherwise, the term “perovskite” as used herein includes each of a true corner-sharing ABX3 perovskite, as illustrated in FIGS. 2A, 2B, and Panel A of FIG. 3A, as well as perovskite-like compositions having 0D, 1D, and/or 2D structures like those shown in FIG. 4, as well as non-perovskites as illustrated in Panels B and C of FIG. 3B, respectively.

In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C1-20 alkyl ammonium cation, a C1-6 alkyl ammonium cation, a C2-6 alkyl ammonium cation, a C1-5 alkyl ammonium cation, a C1-4 alkyl ammonium cation, a C1-3 alkyl ammonium cation, a C1-2 alkyl ammonium cation, and/or a C1 alkyl ammonium cation. Further examples of organic A-cations 110 include methyl ammonium (CH₃NH₃₊), ethyl ammonium (CH₃CH₂NH₃⁺), propyl ammonium (CH₃CH₂ CH₂NH₃⁺), butyl ammonium (CH₃CH₂ CH₂ CH₂NH₃⁺), formamidinium (NH₂CH═NH₂⁺), hydrazinium, acetyl ammonium, dimethyl ammonium, imidazolium, guanidinium, benzyl ammonium, phenethyl ammonium, butyl ammonium and/or any other suitable nitrogen-containing or organic compound. In other examples, an A-cation 110 may include an alkyl amine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g., fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX3 to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

For example, a perovskite having the basic crystal structure illustrated in FIGS. 2A and 2B, in at least one of a cubic, orthorhombic, and/or tetragonal structure, may have other compositions resulting from the combination of the cations having various valence states in addition to the 2+ state and/or 1+ state described above for lead and alkyl ammonium cations; e.g., compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B^{I+}B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

Describe below are more details regarding the use of alkyl ammonium additive molecules to relieve the residual stress within perovskite layers of device stacks (e.g., PSCs). The approach described, among other things, reduces the residual stress and strain to near-zero values at room temperature and prevents cracking and delamination during intense and rapid thermal cycling. The benefits provided by this approach is demonstrated for both, high-efficiency n-i-p (regular) and p-i-n (inverted) perovskite solar cells and minimodules, where both types of solar cells maintained over 80% of their initial PCE after 2,500 thermal cycles in the temperature range −40° C. to 85° C. In addition, without wishing to be bound by theory, the mechanisms by which stress engineering mitigates thermal-cycling fatigue in these perovskite PVs are elucidated herein.

In some embodiments of the present disclosure, control over the residual stress in perovskite layers (e.g., first layers 110) after thermal annealing is achieved by incorporating alkyl ammonium molecules of n-octyl ammonium iodide (OAI) in perovskite layers. As described herein, due to the relatively large size of OA⁺, the OAI molecules incorporate at grain boundaries and interfaces during perovskite formation and relieve internal stress (from +23.4 MPA to ˜0 MPa) at room temperature (RT). This method not only results in increased PCEs for both p-i-n and n-i-p PSCs and perovskite solar modules (PSMs) but more importantly also results in improved thermal cycling lifetimes: n80 under IEC 61215:2016 standard test qualification of 500 cycles for PSCs and PSMs, and 2,500 cycles in an accelerated thermal-cycling test. The thermal-cycling performance of PSCs and PSMs reveals that minimizing the residual stresses at RT in the perovskite layers reduce residual stresses across the temperature range and prevents further interface delamination in layered PV devices during thermal-cycling.

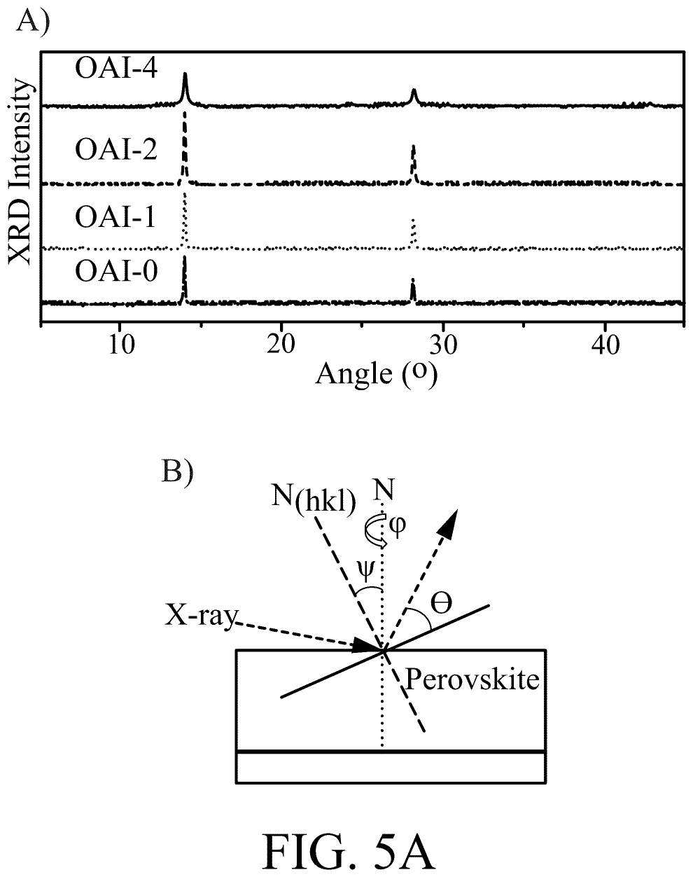

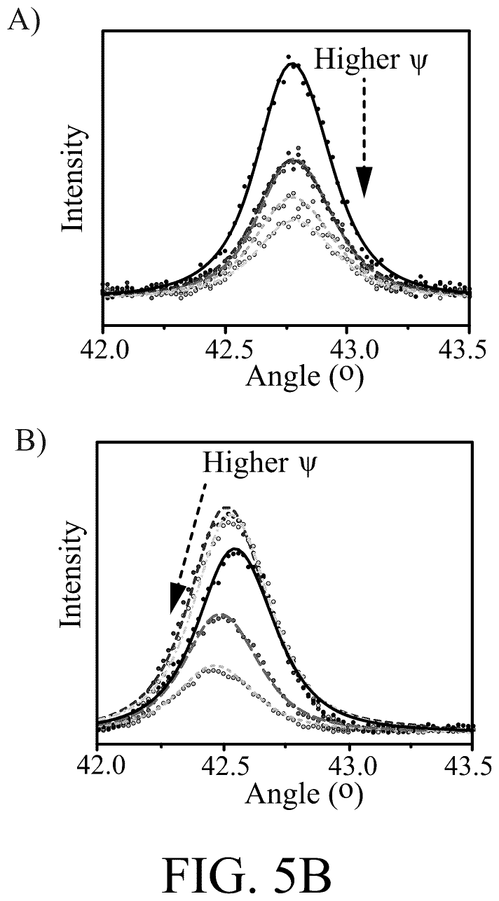

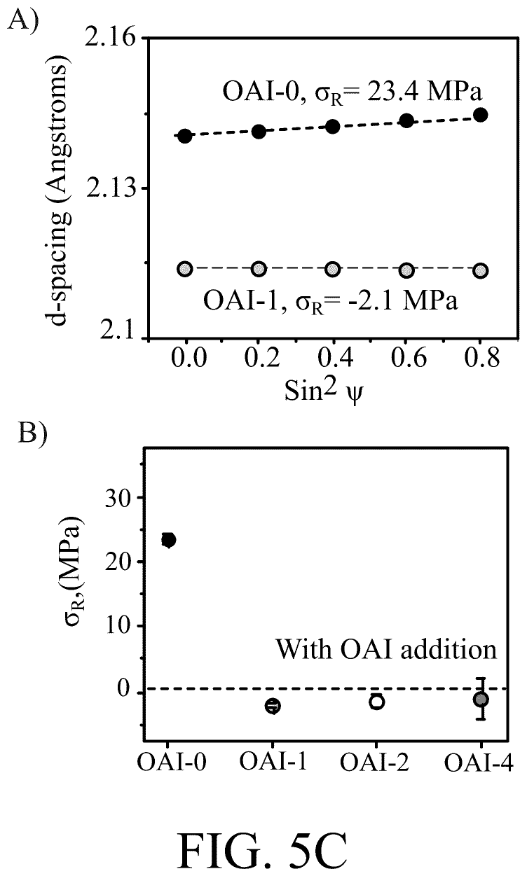

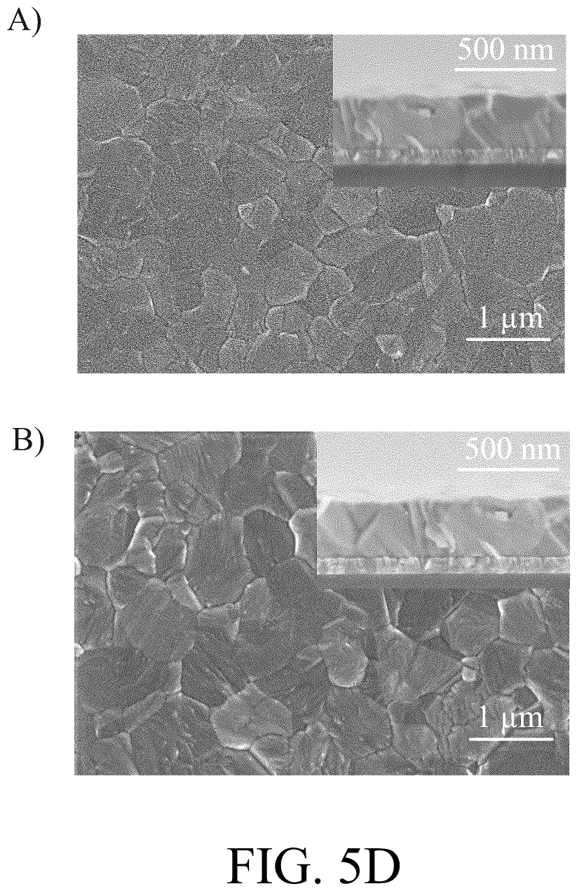

A mixed-composition metal halide perovskite (MHP), (FAPbI₃)_{0.95}(MAPbBr₃)_{0.05} was chosen for a perovskite layer (e.g., first layer 110) for its typically high PCE and thermal stability, and SnO₂ was chosen for an ETL (e.g., second layer 120) since it offers more favorable energy-level alignment with MHP and less possible photocatalytic degradation with MHP compared with TiO₂ in the n-i-p geometry. However, other perovskite compositions may also, and likely will benefit from the use of additives as described herein. Various additive alkyl ammonium halides were tested and the results show that the use of n-octyl ammonium iodide with alkyl (CH₂)ₙ (n=8) linker reduced residual internal stress in perovskite layers. Additionally, different amounts (0, 1 mol %, 2 mol %, 4 mol %) of OAI were dissolved in the perovskite precursor solutions before spin coating and a set of perovskite layers with 0, 1 mol %, 2 mol %, 4 mol % of OAI were synthesized, designated as OAI-0, OAI-1, OAI-2 and OAI-4 respectively. These percentages are relative to the moles of B-site cation used in the perovskite precursor solution for attaining a target perovskite crystal composition. For example, if 100 moles of Pb are added to a perovskite precursor solution, 2 moles of OIA are added. Panel A of FIG. 5A shows XRD results for the set of perovskite layers prepared following spin coating and thermal annealing at 100° C. for 40 minutes.

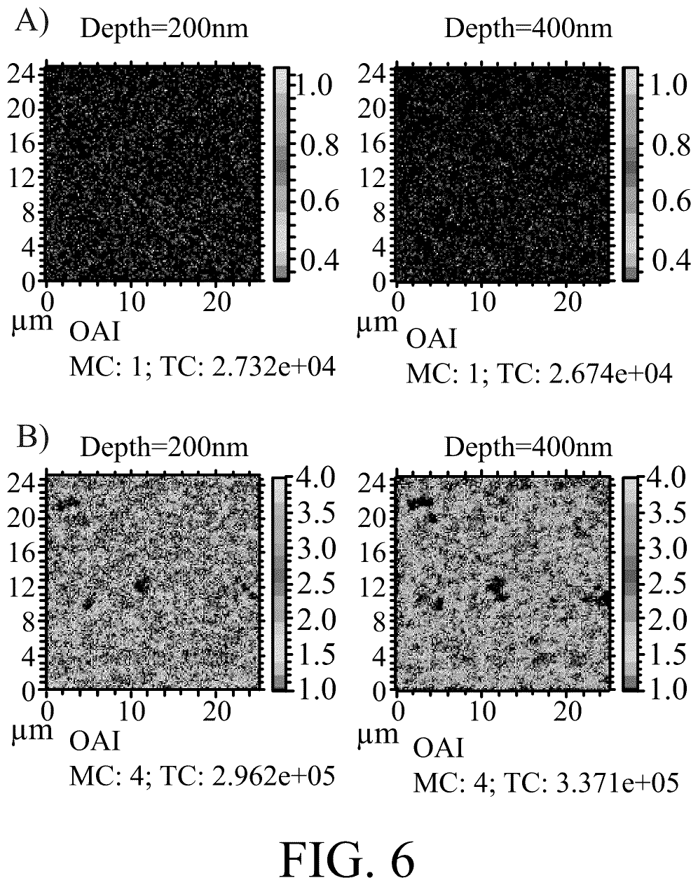

These plots show a drop in the XRD intensity in the perovskite layer having 4 mol % OAI (OAI-4) while the XRD intensity of the perovskite layers having 1 mol % OAI and 2 mol % OAI (OAI-1 and OAI-2, respectively) in (001) and (002) peaks are almost the same. The higher concentration of OAI in the 4 mol % perovskite layer slowed grain growth during thermal annealing, resulting in the lower XRD intensity seen in Panel A of FIG. 5A. Time-of-flight secondary ion mass spectrometry (ToF-SIMS) was used to track the alkyl chain with its specific mass signature and confirm the location of additional OAI. The corresponding TOF-SIMS maps are included in FIG. 6, which show rather uniform spatial distribution in the (Panel A) 1 mol % OAI perovskite layer (OAI-1) and the (Panel B) 4 mol % OAI perovskite layer (OAI-4). These results indicate that the OAI molecules are most likely located at the perovskite grain boundaries. The XRD Sin² ψ method (see Panel B of FIG. 5A) was found to be an accurate and sensitive method to probe the residual internal stress/strain in perovskite layers to evaluate the effects of utilizing different amounts of OAI.

In Panel A FIG. 5C, the (220) interplanar spacing (d₂₂₀) is plotted as a function of sin²ψ for perovskite layers lacking OAI (OAI-0) and perovskite layers having 1 mol % OAI (OAI-1), respectively. A positive slope (m) of the linear fit to the d₂₂₀-sin² ψ data for the perovskite layer lacking OAI indicates the presence of residual biaxial tensile residual stress (or strain). In contrast, the perovskite layer having 1 mol % OAI (OAI-1) shows a much lower negative slope. The biaxial residual stress can be calculated using the following equation:

$${σ}_{R} = ( \frac{{E}_{〈 220 〉}}{1 + v} ) ( \frac{m}{{d}_{n}} )$$

where m is the slope of the linear fit to the data, dₙ is the d₂₂₀ spacing at sin² ψ=0 (y intercept), E_{<220>} is Young's modulus in the <220> direction, and v is the Poisson ratio. E_{<220>} is estimated as 12 GPa. The typical v value of 0.33 is assumed. The calculated residual internal stresses for the set of perovskite layers are summarized in Panel B of FIG. 5C. Overall, the tensile stress in the perovskite layer lacking OIA (OAI-0) is calculated to be 23.4 MPa, which is dramatically reduced to almost 0 MPa in the layers containing 1 mol %, 2 mol %, and 4 mol % OAI (OAI-1, OAI-2, and OAI-4, respectively). Based on that, the perovskite layers synthesized without OAI and containing 1 mol % OAI were chosen for further morphology characterization using scanning electron microscope (SEM). The SEM images shown in Panels A and B of FIG. 5D illustrate that the average apparent grain size of in the perovskite layer lacking OAI (OAI-0) and containing 1 mol % OAI (OAI-1) is approximately 810 nm and 820 nm, respectively.

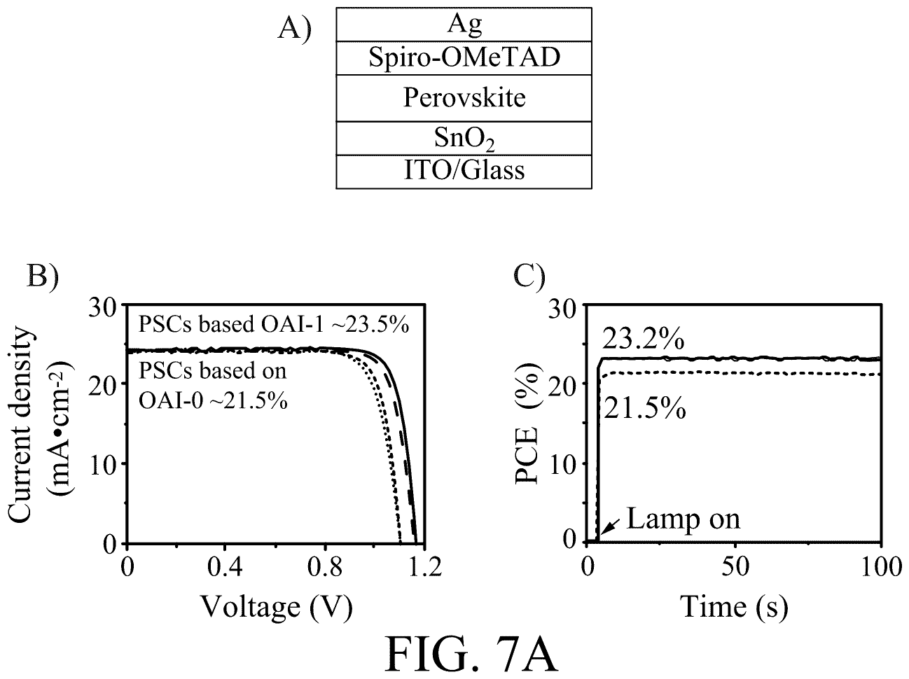

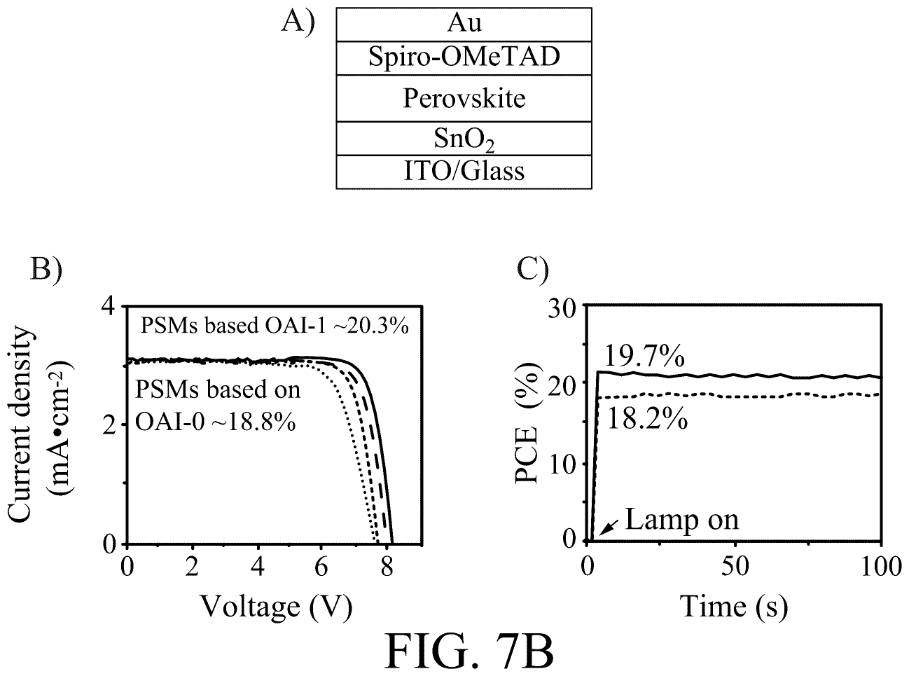

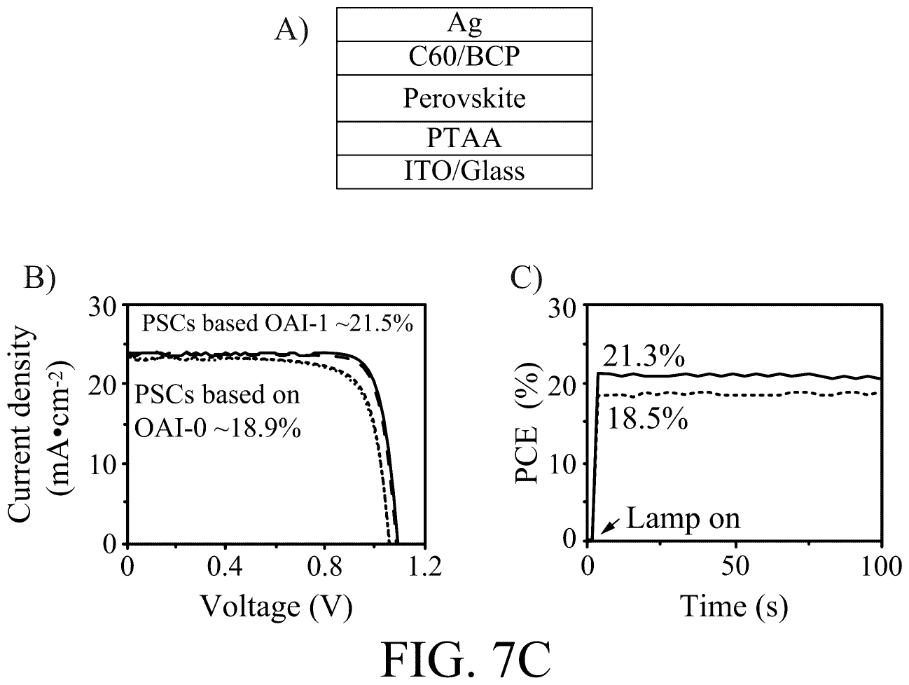

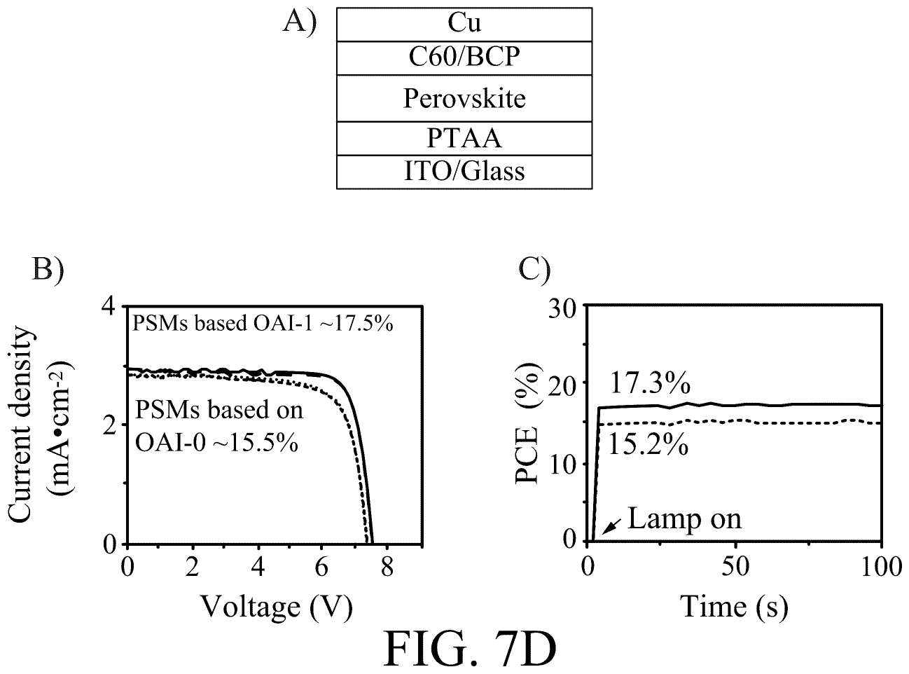

To examine the PV performance, PSCs having perovskite layers lacking OAI (OAI-0) and perovskite layers including 1 mol % OAI (OAI-1) were then prepared in both planar n-i-p and p-i-n device structures. Panel A of FIG. 7A illustrates an n-i-p device structure of an exemplary PSC having the following stack architecture: glass/ITO/SnO₂/perovskite/Spiro-OMeTAD/Ag (glass/ITO/second layer 120/first layer 110/third layer 130/Ag). Panel A of FIG. 7C illustrates a p-i-n device structure having the following stack architecture: glass/ITO/poly(bis(4-phenyl)(2,4,6-trimethylphenyl)amine) (PTAA)/Perovskite/C₆₀/bathocuproine (BCP)/Ag (glass/ITO/third layer 130/first layer 110/second layer 120/C₆₀/BCP), respectively. The perovskite composition used in the perovskite layers as the same for both n-i-p and n-i-p devices.

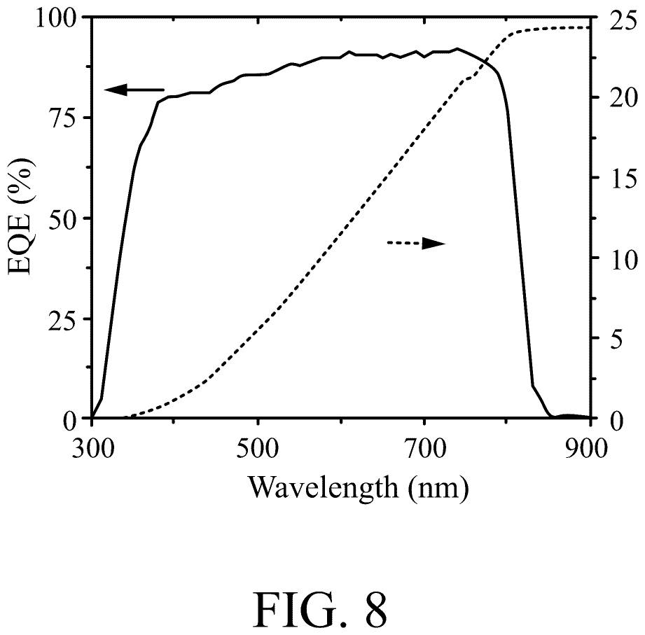

The current density (J)-voltage (V) response under AM1.5G of the best performing n-i-p and p-i-n PSCs based on perovskite layers lacking OAI (OAI-0) and perovskite layers synthesized using 1 mol % OAI (OAI-1) are presented in Panel B of FIGS. 7A and 7C, and the corresponding PV performance parameters are listed in Table 1. The OAI addition increased the open-circuit voltage (V_{OC}) relative to the PSCs lacking OAI in the perovskite layer from 1.11 to 1.17 V in n-i-p and 1.06 to 1.09 V in p-i-n devices, with little hysteresis. The short-circuit current density (J_{SC}) values for the champion PSC based on perovskite layers having 1 mol % OAI (OAI-1) compared favorably with the respective values derived from the external quantum efficiency (EQE) spectra of the PSC based on perovskite layers having 1 mol % OAI (OAI-1) (see FIG. 8).

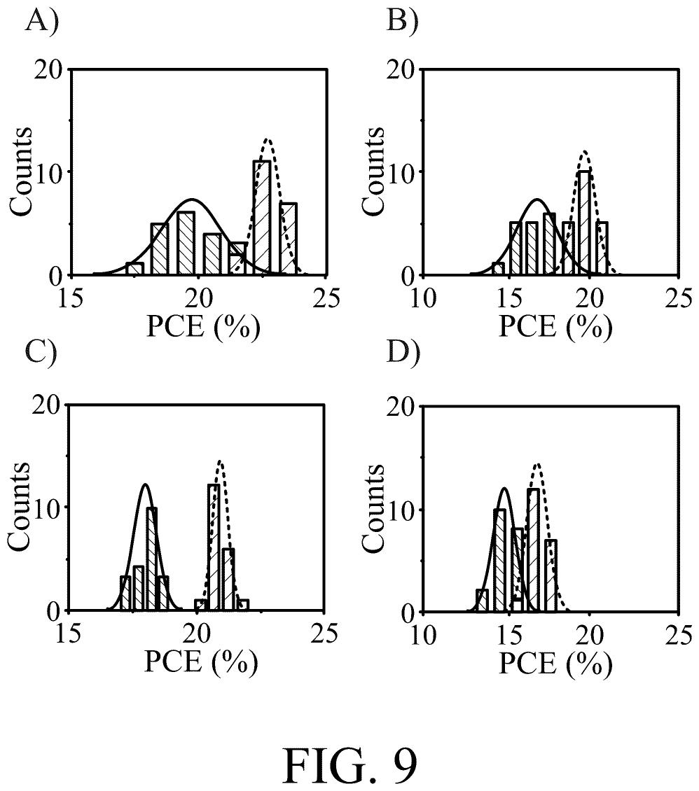

The stabilized PCE output at the maximum power point (MPP) of these PSCs is illustrated in Panel C of FIGS. 7A and 7B. Statistics for the PV performance parameters J_{SC}, V_{OC}, fill factor (FF), and PCE for PSCs (20 cells or modules of each type) are presented in FIG. 9, demonstrating reproducibility. Both n-i-p and p-i-n perovskite solar modules (PSMs) were also produced, based on perovskite layers lacking OAI (OAI-0) and perovskite layers containing 1 mol % OAI (OAI-1). The J-V response of the best performing n-i-p and p-i-n PSMs are shown in Panels B of FIGS. 7B and 7D, illustrating the 20.3% for n-i-p PSM and 17.5% for p-i-n PSM. The corresponding PV performance parameters are listed in Table 1 below.

TABLE 1
PV parameters for all PV devices.

| | PSCs | PSCs | PSCs | PSCs |
|---|---|---|---|---|
| | based | based | based | based |
| | OAI-1 | OAI-1 | OAI-0 | OAI-0 |
| | Reverse | Forward | Reverse | Forward |
| | Scan | Scan | Scan | Scan |
| PCE (%) | 23.6 | 23.1 | 21.47 | 21.2 |
| Voc (V) | 1.17 | 1.17 | 1.11 | 1.11 |
| Jsc (mA · cm⁻²) | 24.55 | 24.42 | 24.27 | 24.32 |
| FF | 82.2 | 80.9 | 79.7 | 78.5 |
| | PSMs | PSMs | PSMs | PSMs |
| | based | based | based | based |
| | OAI-1 | OAI-1 | OAI-0 | OAI-0 |
| | Reverse | Forward | Reverse | Forward |
| | Scan | Scan | Scan | Scan |
| PCE (%) | 20.3 | 19.5 | 18.8 | 17.32 |
| Voc (V) | 8.08 | 7.97 | 7.69 | 7.65 |
| Jsc (mA · cm⁻²) | 3.1 | 3.08 | 3.09 | 3.05 |
| FF | 81.0 | 79.4 | 79.1 | 74.2 |
| | PSCs | PSCs | PSCs | PSCs |
| | based | based | based | based |
| | OAI-1 | OAI-1 | OAI-0 | OAI-0 |
| | Reverse | Forward | Reverse | Forward |
| | Scan | Scan | Scan | Scan |
| PCE (%) | 21.6 | 21.4 | 18.9 | 18.64 |
| Voc (V) | 1.09 | 1.09 | 1.06 | 1.06 |
| Jsc (mA · cm⁻²) | 24.05 | 24.03 | 23.43 | 23.42 |
| FF | 82.4 | 81.8 | 76.1 | 75.1 |
| | PSMs | PSMs | PSMs | PSMs |
| | based | based | based | based |
| | OAI-1 | OAI-1 | OAI-0 | OAI-0 |
| | Reverse | Forward | Reverse | Forward |
| | Scan | Scan | Scan | Scan |
| PCE (%) | 17.5 | 17.4 | 15.5 | 15.4 |
| Voc (V) | 7.45 | 7.43 | 7.24 | 7.24 |
| Jsc (mA · cm₋₂) | 2.92 | 2.92 | 2.85 | 2.84 |
| FF | 80.4 | 80.2 | 75.1 | 74.9 |

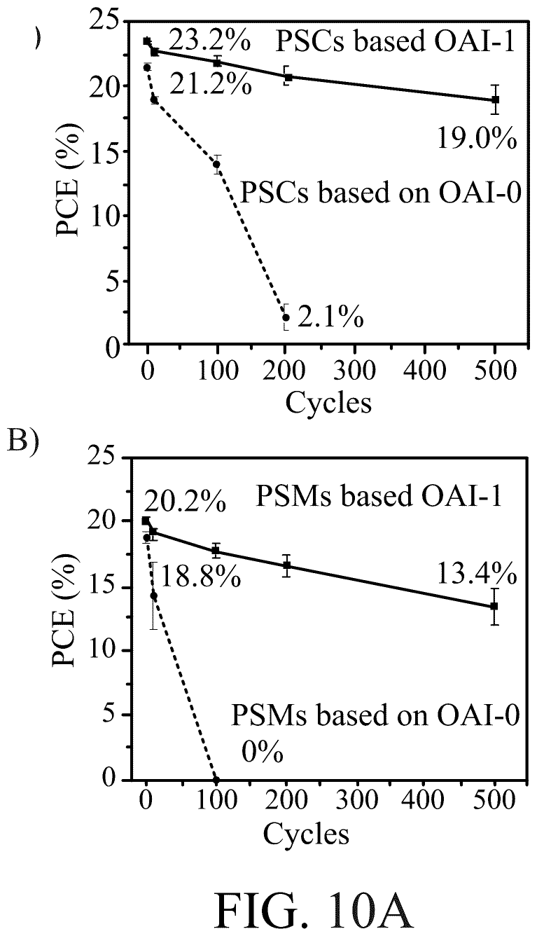

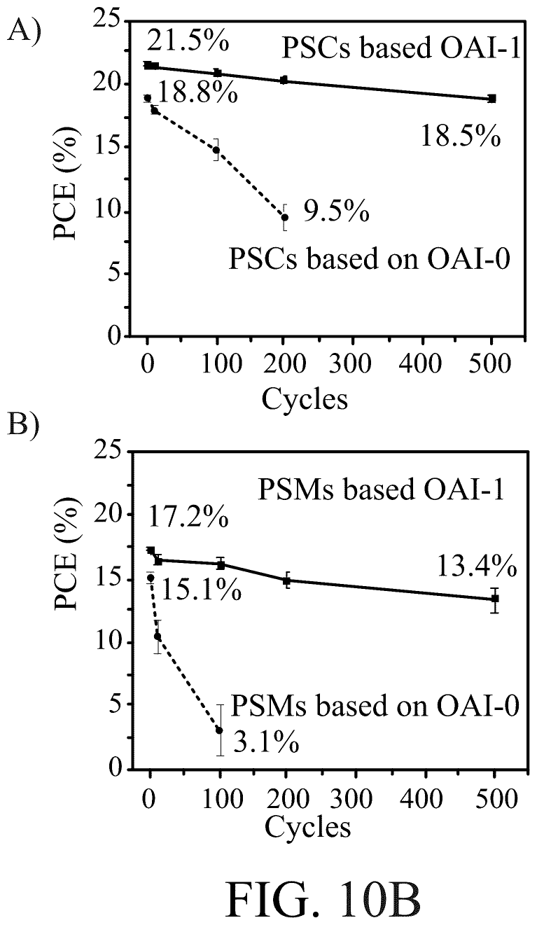

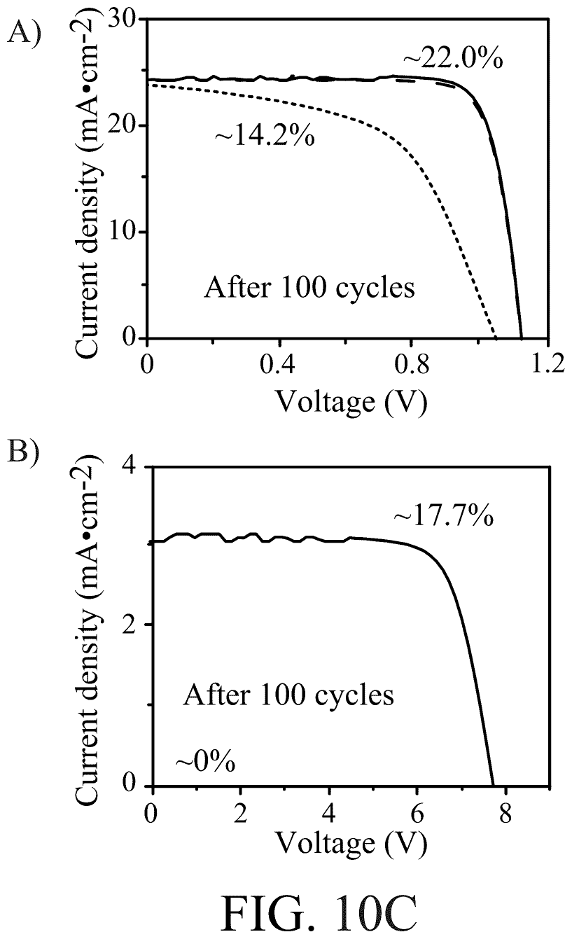

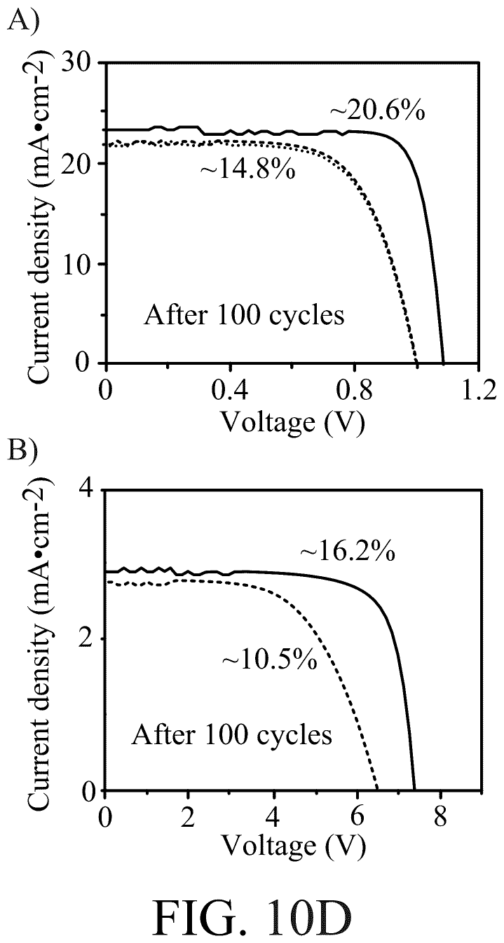

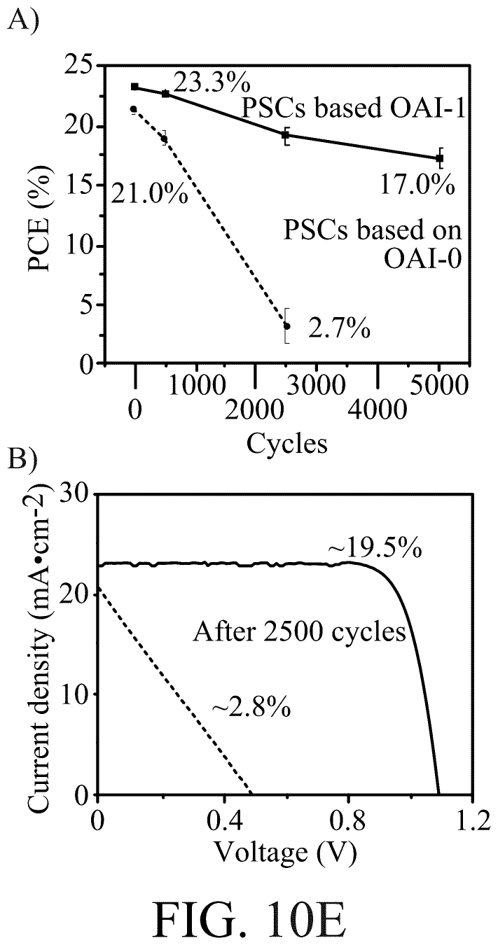

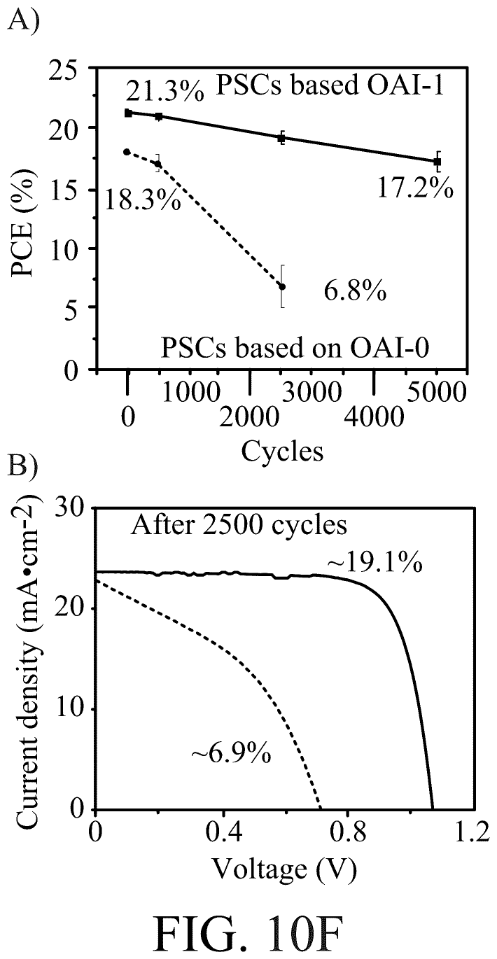

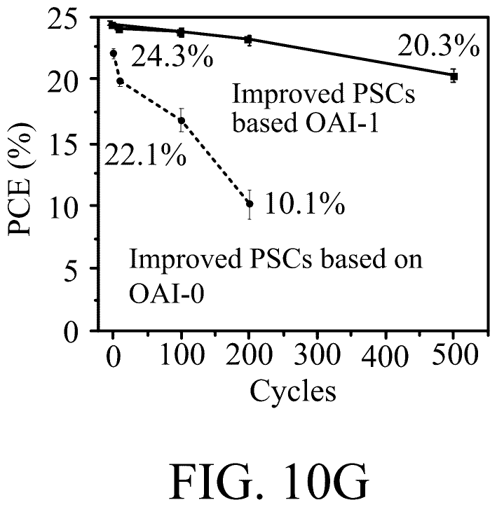

All PSCs and PSMs based on perovskite layers lacking OAI (OAI-0) and perovskite layers containing 1 mol % OAI (OAI-1) were tested further in a closed chamber for thermal cycling under IEC 61215:2016 qualification (−40° C. to 85° C., N2, 6 hours per cycle). For n-i-p PSCs and PSMs, the PCE of PSCs based on perovskite layers lacking OAI dropped quickly from initial 21.2% to 2.1% after 200 cycles while the PCE of PSCs based on perovskite layers containing 1 mol % OAI (OAI-1) dropped to 19.0% (82% of initial PCE of 23.2%). However, much faster degradation was seen in n-i-p PSMs without the OAI additive (OAI-0) dropping to 0% after 100 cycles. The PCE of n-i-p PSM based on a perovskite layer containing 1 mol % (OAI-1) decreased to 17.7% after 100 cycles and 13.4% after 500 cycles. For p-i-n PSCs and PSMs, the PCE of PSCs based on a perovskite layer lacking OAI (OAI-0) dropped to 9.5% from initial 18.5% after 200 cycles while the PCE of PSCs based on a perovskite layer containing 1 mol % (OAI-1) dropped to 20.2% (94% of initial PCE). The J-V curves for PSCs and PSMs after 100 cycles are shown in FIGS. 10C-10F, demonstrating the main loss comes from the FF and V_{OC}. Both n-i-p and p-i-n PSCs demonstrated a turning point (100 cycles for n-i-p PSCs and p-i-n PSCs) from slower decay to faster decay.

n-i-p and p-i-n PSCs were also evaluated in accelerated thermal cycling tests. The thermal cycling test is set as −40° C. to 85° C. with 5 minutes per cycle, which means much harsher cycling conditions for PSCs. The n-i-p and p-i-n PSCs based on perovskite layers containing 1 mol % OAI (OAI-1) still maintains 72% and 81% after 5000 cycles while the n-i-p and p-i-n PSCs based on perovskite layers lacking OAI (OAI-0) only retains 13% and 37% after 2500 cycles. From the J-V response of the n-i-p (see Panel B of FIG. 10E) and p-i-n (see Panel B of FIG. 10F) PSCs based on perovskite layers with 1 mol % OAI and lacking OAI, the main loss of PV performance during thermal cycling is due to the dropping of V_{OC} and FF consistent with observation for the PCE evolution during standard thermal cycling.

Furthermore, in p-i-n PSCs, the perovskite composition was modified and improved the PCE of p-i-n solar cells based on a perovskite layer having 1 mol % OAI (OAI-1) to 24.3%. The improved p-i-n solar cells based on a perovskite layer having 1 mol % OAI (OAI-1) are more resistant to degradation than the improved p-i-n cells based on OAI-0 in thermal cycling test (see FIG. 10G.).

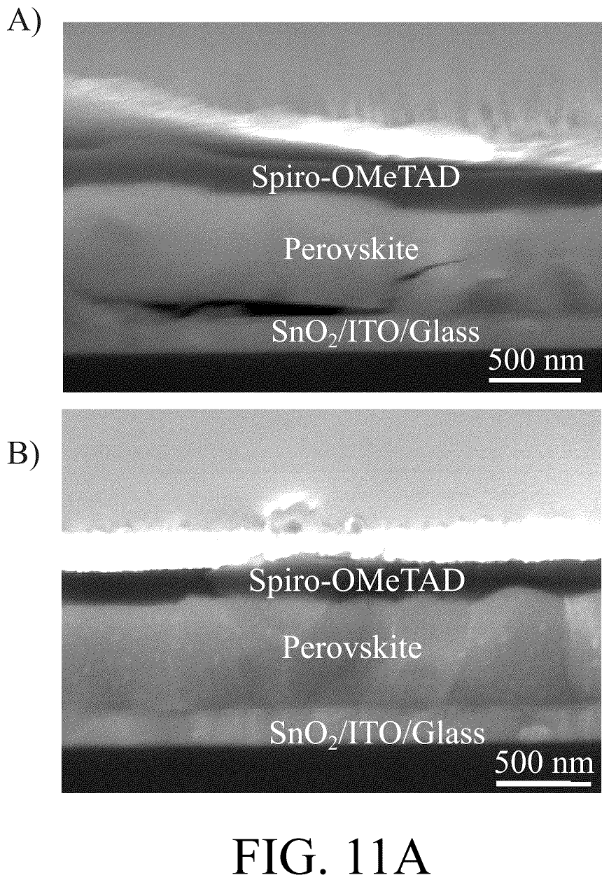

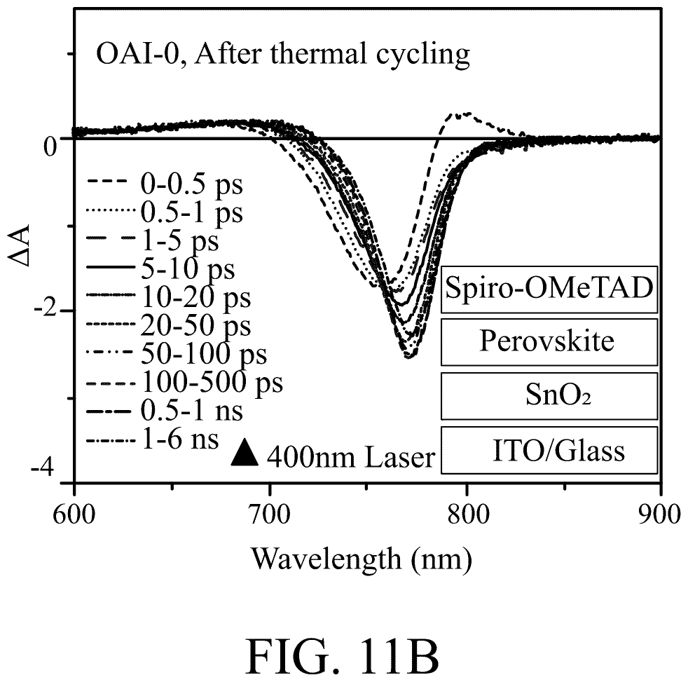

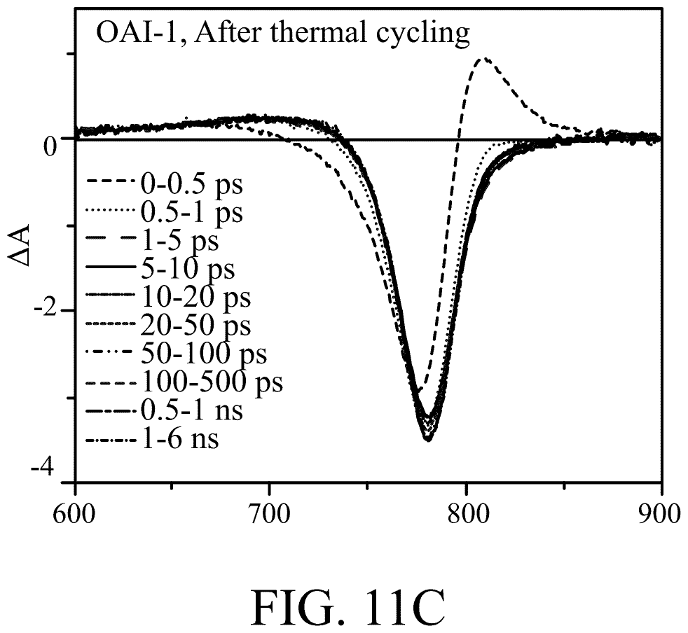

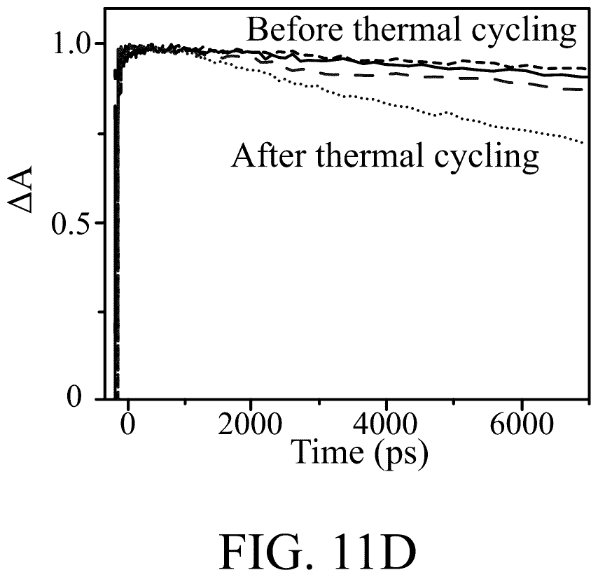

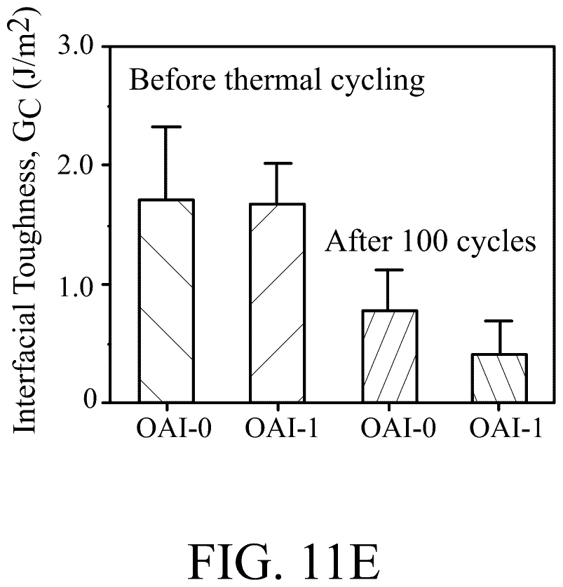

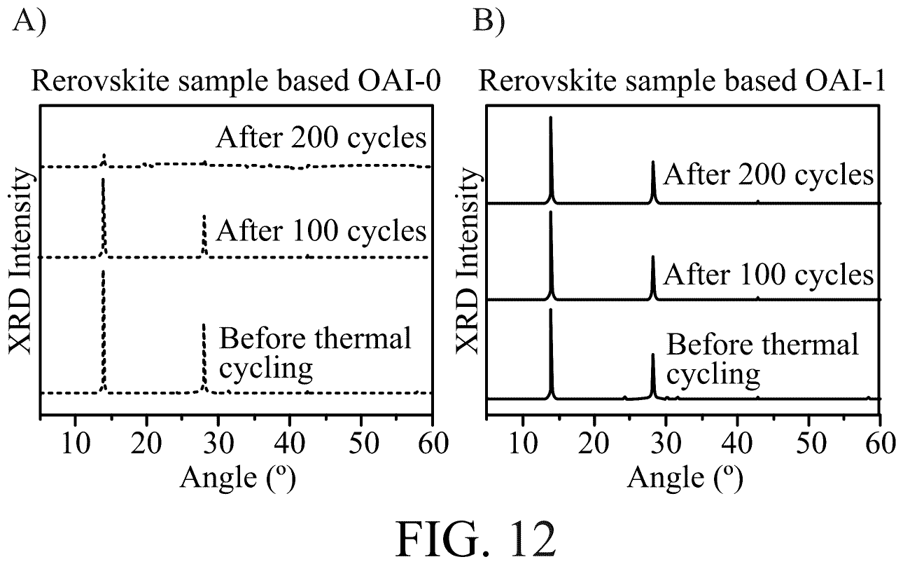

Cross-sectional SEM images of the PSC based on perovskite layers lacking OAI (OAI-0) after 100 cycles (see Panel A of FIG. 11A) shows two types of irreversible morphological degradation features at the interface: cracks in grains and delamination between the perovskite layer and SnO₂ layer at the interface between those two layers. In contrast, such degradation features were not seen when compared with the corresponding SEM image of the PSC based on a perovskite layer having 1 mol % OAI (OAI-1) (see Panel B of FIG. 11A). XRD was performed for PSCs based on perovskite layers lacking OAI and perovskite layers including 1 mol % OAI after different thermal cycles (see FIG. 12). Before reaching 100 cycles, no additional XRD peaks of PSCs but only a small decrease (˜5%) in the XRD peak intensity could be observed in the perovskite layer. However, after 100 cycles, peaks with much lower intensity (˜35% drop) could be observed in the PSCs based on the perovskite layer lacking OAI, indicating an accelerated structural disorder of perovskite materials after delamination effect in PSCs.

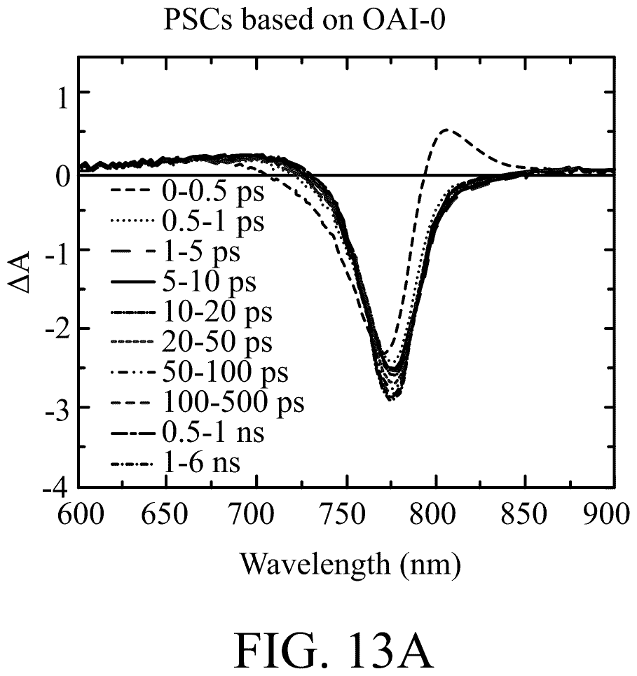

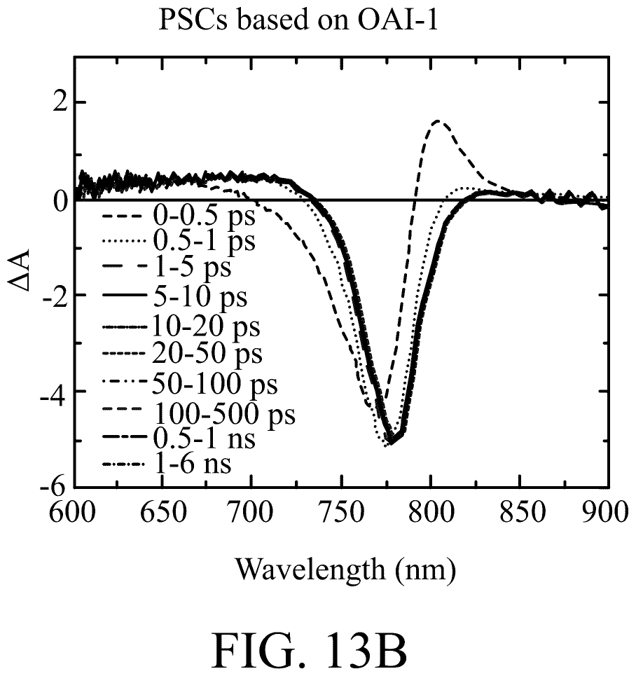

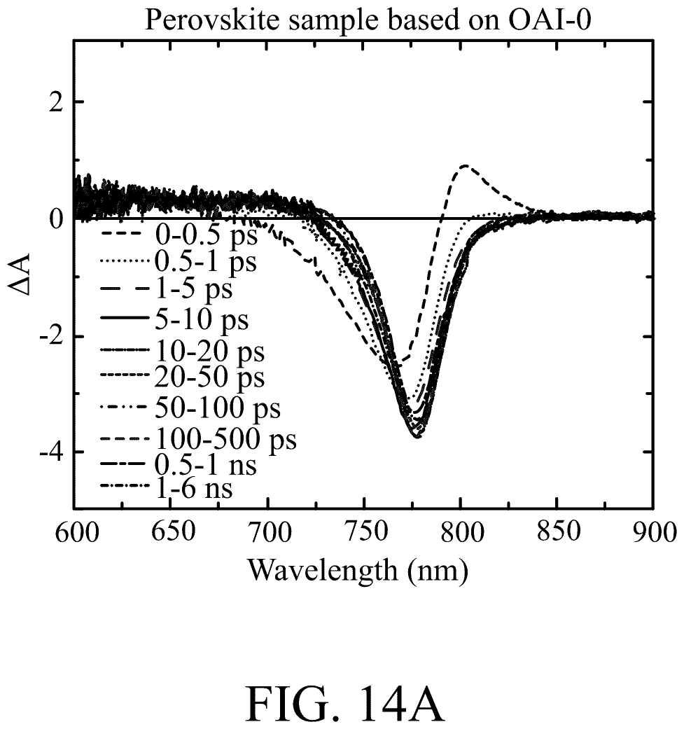

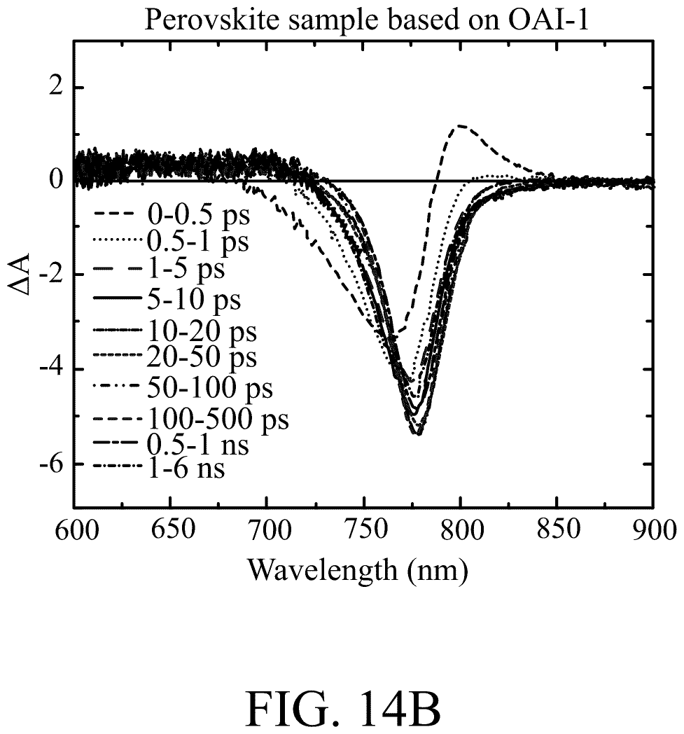

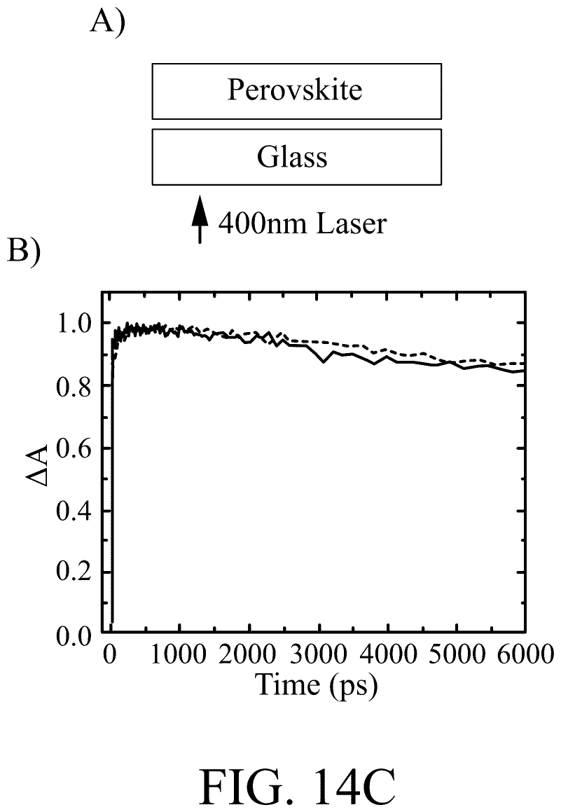

The PSCs based on perovskite layers lacking OAI and perovskite layers including 1 mol % OAI before (see FIGS. 13A and 13B) and after thermal cycling of 100 cycles were also examined by the transient absorption (TA) spectroscopy. A laser with a wavelength of 400 nm was used to illuminate from the glass side so the TA signal was predominantly generated from the interface formed between the perovskite layer and the SnO₂ layer, enabling the measurement of photo-carriers generated from the interface of perovskite and SnO₂ layer before and after thermal cycling test. Perovskite precursor solutions without additives (OAI-0) and with 1 mol % OIA (OAI-1) were deposited on glass/ITO substrates. After 100 thermal cycles, the TA kinetics results (see FIGS. 14A and 14B) show negligible difference between the OAI-O sample and OAI-1 sample. However, after thermal cycling of 100 cycles, compared with TA kinetics results of pure OAI-0 and OAI-1, a clear shorter lifetime was observed in PSC based on OAI-0. This is probably the single-layer-passivation characteristic from the HTL/perovskite interface because of delamination between ETL and perovskite layer shown in SEM image illustrated in Panel A of FIG. 11A.

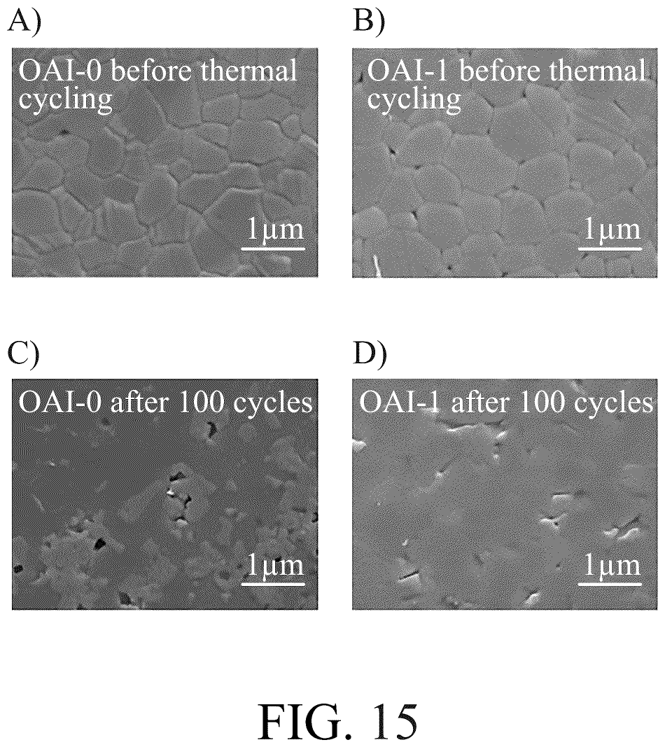

The delamination effect was also examined by measuring the interfacial toughness (G_{C}) between the perovskite layers and ETL layers before and after thermal cycling (see FIG. 11E). The G_{C} value before thermal cycling shows negligible differences for the PSCs based on perovskite layers lacking OAI (OAI-0) (1.67±0.32 J/m²) and perovskite layers synthesized using 1 mol % OAI (OAI-1) (1.71±0.45 J/m²). After 100 thermal cycling cycles, the G_{C} value inevitably decreased to the 0.41±0.25 for PSCs based on OAI-free perovskite layers and 0.78±0.22 J/m² for perovskite layers synthesized with 1 mol % (OAI-1) (see FIG. 11E). The fractured surfaces (before and after thermal cycling) are illustrated in FIG. 15, which indicates the beneficial effect of OAI in preserving the mechanical integrity of that buried interface during thermal cycling. For the PSCs based on perovskite layers formed without OAI, the neutral residual stress of such perovskite layers at room temperature could avoid the extreme high value in residual stress due to temperature change in thermal cycling test. However, the residual tensile stress in the PSCs based on perovskite layers synthesized using 1 mol % OAI (OAI-1) reduces the interfacial toughness due to high residual stress and corresponding thermal cycling fatigue. Taken together, these results suggest that stress engineering of perovskite layers in PSCs or PSMs is an effective approach to significantly enhance the thermal cycling performance of perovskite PV devices.

### Experimental:

Materials: All materials used in the experiments were obtained commercially and used without further purification, which include: N,N-dimethylformamide (DMF; 99.8%, Sigma-Alrdich, USA), dimethyl sulfoxide (DMSO; 99.7%, Sigma-Alrdich, USA), cesium iodide (CsI; 99.999%, Alfa-Aesar, USA), formamidinium iodide (FAI; Greatcell Solar, Australia), methylammonium bromide (MABr; Greatcell Solar, Australia), Pb(II) iodide (PbI2; 99.99%, TCI), Pb(II) bromide (PbBr₂; >98%, Sigma-Aldrich, USA), chlorobenzene (CB; 99.8%, Sigma-Aldrich, USA), isopropanol (IPA; 99.5%, Sigma-Aldrich, USA), Spiro-OMeTAD (Sigma-Alrdich, USA, bis(trifluoromethane)sulfonimide lithium salt (LiTFSI; 99.95%, Sigma-Aldrich, USA), acetonitrile (ACN; 99.9%, Acros Organics, USA), 4-tert-butylpyridine (t-BP; 96%, Sigma-Aldrich, USA), [6,6]-phenyl-C₆₁-butyric acid methyl ester (PCBM; 1-Material, Canada), Bathocuproine (BCP; 1-Material, Canada), tin oxide nanoparticles (SnO₂; 15% in H₂O, Alfa-Aesar, USA), poly(methyl methacrylate) (PMMA; Sigma-Aldrich, USA), and epoxy adhesive (Hysol, USA), n-octyl ammonium iodide (OAI, Greatcell Solar, Australia).

Device Fabrication: n-i-p perovskite solar cells (PSCs) were fabricated with the following structure: ITO/SnO₂/Perovskite/Spiro-OMeTAD/Ag. The ITO-coated glass was pre-cleaned successively in ultrasonic baths of detergent solution, deionized water, ethanol, acetone, and isopropanol, for 30 minutes each, and further treated with UV-ozone for 15 minutes. A dilute SnO₂ nanoparticle solution (IPA:Water:SnO₂ nanoparticle solution directly from Alfa Aesar=3:3:1) was spin-coated onto the substrates at 3000 rpm for 30 seconds and annealed at 150° C. for 30 minutes to form a compact SnO₂ electron transport layer. Precursor solution was prepared by dissolving PbI₂ (0.5827 g) MABr (0.0071 g) PbBr₂ (0.0232 g) MACI (0.030 g) FAI (0.2173 g) in DMF (0.8 ml) & DMSO (0.1 ml) with different amounts (0%, 1%, 2%, 5%: mol % of additive relative to the moles of B-site cation used for the target perovskite crystal, in this lead) of OAI. The perovskite precursor solution is deposited by spin-coating at 500 rpm 5 seconds, then 1000 rpm 5 seconds, then 2750 rpm 20 seconds (during the last 5 seconds, gently and consistently dripping 1 ml diethyl ether (DEE) by using a specialized 1 ml displacement diethyl ether (DEE) gun). Subsequently, the as-deposited layers were annealed at 120° C. for 40 minutes. The Spiro-OMeTAD solution was prepared by dissolving 72.5 mg of Spiro-OMeTAD with additives in 1000 μL of chlorobenzene. 17.5 μL of Li-TFSI solution (520 mg·mL⁻¹ in ACN), and 29.5 μL of t-BP were added to the solution. The Spiro-OMeTAD hole transport layer solution was deposited by spin-coating the solution at 3000 rpm for 30 seconds. Both of MHP and HTL deposition were performed in a humidity-controlled (˜15% RH) hood. Finally, 80-nm of Ag layer was thermally-evaporated on top of the HTL as an electrode.

For p-i-n solar cells, a hole transport layer (HTL) poly(bis(4-phenyl)(2,4,6-trimethylphenyl)amine) (PTAA) with a concentration of 2 mg/mL dissolved in toluene was spin coated at the speed of 6,000 rpm for 35 seconds and then annealed at 100° C. for 10 minutes. 150 ul of the perovskite precursor solution was spun onto PTAA at 4,000 rpm for 30 seconds, and the sample was washed with 150 μL toluene/CB at 5 seconds before the end of the spinning. Subsequently, the sample was annealed at 100° C. for 30 minutes. The devices were finished by thermally evaporating C60 (20 nm), BCP (8 nm), and silver (80 nm) in sequential order.

The n-i-p module composed of eight-strip cells connected in series using P1, P2, P3 type interconnects. The laser structuring of all three scribes (P1, P2, P3) were made with the same near infrared 1064 nm 20 W laser (Trotec). For fabrication of solar modules, 6.5 cm×7 cm FTO substrates were patterned by a laser with a scribing width of 40 μm (Speed 300 mm/s, frequency 65 kHz, pulse duration: 120 ns, power 60%). FTO glass (Nippon Sheet Glass) was cleaned with detergent solution, acetone, and isopropanol. The substrate was spin coated with a layer of SnO₂ nanoparticle layer at 3000 rpm for 30 seconds with a ramp-up of 1500 rpm·s⁻¹ from a commercially available solution in water; the weight ratio of SnO₂ solution to water is 1:3. After spin coating, the substrate was immediately dried on a hotplate at 80° C., and the substrates were then heated at 190° C. for 30 minutes. Before using, the substrate was cleaned by UVO for 15 minutes. Next, the perovksite layers was deposited as described in the n-i-p solar cells. The HTM solution was prepared by dissolving 91 mg of Spiro-OMeTAD (Merck) with additives in 1 mL of chlorobenzene. As additives, 21 μL of Li-bis(trifluoromethanesulfonyl) imide from the stock solution (520 mg in 1 mL of acetonitrile), 16 μL of FK209 [tris(2-(1H-pyrazol-1-yl)-4-tert-butylpyridine)-cobalt (III) tris(bis(trifluoromethylsulfonyl) imide) (375 mg in 1 mL of acetonitrile) and 36 μL of tBP were added. The HTM layer was formed by spin-coating the solution at 4000 rpm for 20 seconds. Next, FTO/ETL/Perovskite/HTM layers were laser scribed over a width of 400 μm (multiple parallel scribes with 50 micron spacing, speed 1000 mm/s, pulse duration 120 ns, frequency 65 kHz, power 15%). Finally, a gold electrode was deposited by thermal evaporation, and gold layers were scribed by a laser with a scribing width of 50 μm (speed 1000 mm/s, pulse duration 120 ns, frequency 65 kHz, power 15%).

The p-i-n solar module composed of eight-strip cells connected in series using P1, P2, P3 type interconnects. The laser structuring of all three scribes (P1, P2, P3) were made with the same near infrared 1064 nm 20 W laser (Trotec). For fabrication of solar modules, 6.5 cm×7 cm ITO substrates were patterned by a laser with a scribing width of 40 μm (Speed 300 mm/s, frequency 65 kHz, pulse duration: 120 ns, power 60%). ITO glass (Lumitec) was cleaned with detergent solution, acetone, and isopropanol. Then, the substrates were spin-coated with PTAA precursor as described in p-i-n solar cells fabrication, followed by 10 min of annealing at 100° C. After cooling the substrate, perovskite solutions are successively spin-coated on the substrates at 1000 rpm for 10 s and 3000 rpm for 40 seconds, respectively. 1 ml of chlorobenzene was dropped in 25 seconds at 3000 rpm. Perovskite layers were annealed at 100° C. for 40 minutes. Afterwards, samples were transferred to the thermal evaporator for C₆₀ (30 nm)/BCP (6 nm) deposition. Next, ITO/HTL/Perovskite/ETL layers were laser scribed over a width of 400 μm (multiple parallel scribes with 50 micron spacing, speed 1000 mm/s, pulse duration 120 ns, frequency 65 kHz, power 13%). Finally, a copper electrode was deposited by thermal evaporation, and copper layers were scribed by a laser with a scribing width of 50 μm (speed 1000 mm/s, pulse duration 120 ns, frequency 65 kHz, power 14%).

Materials Characterization: A broadband femtosecond-nanosecond transient absorption (TA) spectrometer (Helios, Ultrafast Systems) was used to measure TA spectra and kinetics for layer samples. PHAROS Yb:KGW laser pulse (1030 nm, 1 kHz) was directed to an optical parametric amplifier (ORPHEUS) to generate pump pulses at 400 nm (<200 fs pulse duration) and was modulated at 500 Hz through an optical chopper. The rest of the 1030 nm pulse was routed onto a mechanical delay stage (7 ns time window) and was directed through a sapphire crystal to generate white light probe ranging from 480-950 nm. The pump and probe beams were focused onto the same spot on the samples. The crystal structures of perovskite layers were recorded using an X-ray diffractometer (D-Max 2200, Rigaku, 40 kV, 250 mA). A parallel beam geometry was used for the XRD: Sin² ψ strain measurements. A height and rotation alignment were performed for all samples to avoid peak shifts due to subtle differences in sample heights/thicknesses. Scans of intensity vs 20 are each fit to Pearson VII functions which account for Cu Kα doublet splitting expressed as:

$$f ( x ) = {a ( \frac{1 + {{b}^{2} ( x - c )}^{2}}{m} )}^{- m} + 0.5 {a ( \frac{1 + {{b}^{2} ( x - {A}^{′} ( c ) )}^{2}}{m} )}^{- m}$$

where a, b, c, m are free parameters used for fitting and the second term represents the contribution of the K−α₂ diffraction. Diffraction peaks with sufficiently high signal-to-noise ratios were selected to enable accurate peak position determination. For detailed information on the application of the XRD: Sin²ψ method readers are directed to additional sources. The morphologies and microstructures of the perovskite layers and cross-sectional structures of the solar cells were investigated using a Hitachi S-4800 scanning electron microscope. The J-V curves were measured in a nitrogen glovebox using a Newport Oriel Sol3A class solar simulator with a xenon lamp that was calibrated before use with a silicon cell under a KG2 filter. The SPOs of the devices were measured by monitoring the photocurrent density output evolution under the biased voltage set near the maximum power point.

Mechanical Testing: The “sandwich” double cantilever beam (DCB) specimens were prepared with the following structure: ITO-coated glass/SnO₂/perovskite/PMMA/epoxy/glass. The deposition of SnO₂, perovskite followed afore-mentioned procedures. The PMMA layer was deposited onto perovskite for protection by spin-coating the PMMA solution (10 wt % in chlorobenzene), which was allowed to dry at room temperature for 1 hour. Then, a layer of epoxy was applied onto the PMMA layer to “glue” another cleaned glass substrate on top. For the DCB specimens after thermal cycling, the PMMA layer was deposited after performing thermal cycling of perovskite layers.

The DCB specimens were tested using a method described elsewhere. Briefly, a planar pre-crack was introduced along the width (B=12.5 mm) dimension of the specimen by inserting a razor blade into the “notch.” Initially, a pre-load of 0.2 N was applied to ensure a good contact between the specimen and the instrument. The cracked DCB specimens were then loaded in tension with a displacement rate of 3 μm/s using a delaminator system (DTS, USA) until a well-defined planar crack at the SnO₂/perovskite interface was obtained. The load (P)-displacement (A) response was recorded at all times. The specimen was then partially unloaded, and reloaded where the crack length, a, was estimated using the compliance method, in conjunction with the following relation:

$$a = {( \frac{d Δ}{dP} * \frac{{BEh}^{3}}{8} )}^{\frac{1}{3}} - 0.64 h ,$$

where B (=12.5 mm) and E (=70 GPa) are the width and the Young's modulus of the glass substrate, respectively, and h (=1 mm) is the half-thickness of the DCB specimen. The toughness, G_{C}, is then given by the relation:

$${G}_{C} = \frac{12 {{P}_{C}}^{2} {a}^{2}}{{B}^{2} {Eh}^{3}} {( 1 + 0.64 \frac{h}{a} )}^{2}$$

where P_{C} is the load at the onset of non-linearity in the P−Δ curve during the loading cycle. The loading-unloading cycles were repeated for several times. The average G_{C} is reported for each such test.

Device Characterization: Simulated AM 1.5G irradiation (100 mW/cm²) was produced by an Oriel Sol3A Class AAA Solar Simulator in a nitrogen glovebox for current density-voltage (J-V) measurements. The intensity of the solar simulator was calibrated with a KG5 filtered Si reference solar cell that was certified by NREL PV Performance Characterization Team, and the spectral mismatch factor was minimized to 0.9923. The device area was 0.122 cm² and was masked with a metal aperture to define an active area of 0.0585 cm². The scanning rate was 0.34 V s⁻¹. The stabilized power output (SPO) of the devices was measured by monitoring the photocurrent current density output with the biased voltage set near the maximum power point. EQE measurements were performed in ambient air using a Newport Oriel IQE200 with monochromatic light focused on the device pixels and a chopper frequency of 37 Hz.

### EXAMPLES

Example 1. A device comprising: a first layer comprising a perovskite, the first layer having a thickness (t); and an additive comprising at least one of an aromatic ammonium cation or an alkyl ammonium cation, wherein: the perovskite comprises a plurality of perovskite grains separated by a plurality of grain boundaries, a portion of the additive is positioned at or near the grain boundaries or at a surface of the first layer or a combination thereof, and the first layer is characterized by a stress between −50 MPa and 50 MPa, as measured by x-ray diffraction (XRD) at room temperature.

Example 2. The device of Example 1, wherein the additive further comprises an anion.

Example 3. The device of Example 2, wherein the anion comprises at least one of a halide, a pseudo halide, formate, carbonate, or nitrate.

Example 4. The device of Example 1, wherein a portion of the additive is positioned at or near the grain boundaries.

Example 5. The device of Example 1, wherein the stress is between −5 MPa and 5 MPa or between −1 MPa and 1 MPa.

Example 6. The device of Example 1, wherein the first layer is further characterized by a strain of between −0.1 and 0.1 or between −0.01 and 0.01 (unitless).

Example 7. The device of Example 6, wherein the strain is approximately zero.

Example 8. The device of Example 1, wherein the pseudo halide comprises thiocyanate.

Example 9. The device of Example 1, wherein the first layer has a thickness between 100 nm and 20 μm or between 300 nm and 1 μm.

Example 10. The device of Example 1, wherein the additive has a length between 5 Å and 75 Å or between 15 Å and 25 Å.

Example 11. The device of Example 1, wherein the alkyl group of the alkyl ammonium cation comprises a hydrocarbon group having between 2 and 30 carbon atoms.

Example 12. The device of Example 11, wherein hydrocarbon group comprises a branched hydrocarbon chain.

Example 13. The device of Example 11, wherein hydrocarbon group comprises a straight hydrocarbon chain.

Example 14. The device of Example 13, wherein the straight hydrocarbon chain comprises between 6 and 10 carbon atoms.

Example 15. The device of Example 1, wherein the alkyl ammonium cation comprises n-octyl ammonium.

Example 16. The device of Example 1, wherein the aromatic ammonium cation comprises at least one of benzyl ammonium or methylbenzyl ammonium.

Example 17. The device of Example 16, wherein the anion comprises at least one of iodide, chloride, bromide, formate, carbonate, nitrate, or thiocyanate.

Example 18. The device of Example 1, wherein a portion of the additive is positioned in the first layer at a concentration between greater than 0 mol % and 10 mol % or between greater than 0 mol % and 4 mol %, inclusively.

Example 19. The device of Example 18, wherein a portion of the anion is positioned in the first layer at a concentration between greater than 0 mol % and 10 mol % or between greater than 0 mol % and 4 mol %, inclusively.

Example 20. The device of Example 1, further comprising a second layer, wherein the first layer and the second layer are parallel and adjacent to each other, forming a first interface.

Example 21. The device of Example 20, wherein a portion of the additive is positioned at the first interface.

Example 22. The device of Example 20, wherein the perovskite positioned at and/or near the first interface is characterized by at least one of a stress of about zero or a strain of about zero, as measured by x-ray diffraction (XRD) at room temperature.

Example 23. The device of Example 1, wherein the second layer comprises a first charge transport material.

Example 24. The device of Example 1, further comprising: a third layer, wherein: the first layer is positioned between the second layer and the third layer, the first layer and the third layer are parallel and adjacent to each other, forming a second interface, and the perovskite positioned at and/or near the second interface is characterized by at least one of a stress of about zero or a strain of about zero, as measured by x-ray diffraction (XRD) at room temperature.

Example 25. The device of Example 24, wherein a portion of the additive is positioned at the second interface.

Example 26. The device of Example 24, wherein the third layer comprises a second charge transport material.

Example 27. The device of Example 1, wherein the perovskite comprises a metal halide perovskite.

Example 28. A method comprising: preparing a solution comprising a perovskite precursor and an additive; and applying the solution to a surface, creating a liquid layer of the solution, wherein; the applying results in the forming of a solid perovskite layer comprising a plurality of grains and grain boundaries, the perovskite layer forms an interface between the surface and the perovskite layer, and a portion of the additive is positioned within a grain boundary, at the interface, or a combination thereof.

Example 29. The method of Example 28, wherein the solution comprises an A-site component (A), a B-site component (B), and an X-site component (X) for synthesizing a target perovskite crystal comprising A, B, and X, the solution comprises the additive at a molar concentration between greater than 0 mol % and less than 10 mol %, and the molar concentration is calculated relative to the moles of B added to the solution.

Example 30. The method of Example 29, wherein the molar concentration is between 1 mol % and 5 mol %, inclusively.

Example 31. The method of Example 28, wherein the applying is performed using at least one of spin-coating, blade-coating, curtain-coating, spray-coating, or a combination thereof.

Example 32. The method of Example 28, wherein the solution further comprises a first solvent.

Example 33. The method of Example 32, further comprising: after the applying, contacting at least one of any remaining liquid layer, a partially solidified perovskite layer, or a combination thereof with a second solvent, wherein: the contacting results in the conversion of the remaining liquid layer and the partially solidified perovskite layer to the solid perovskite layer.

Example 34. The method of Example 32, further comprising: after the applying, heating the solid perovskite layer, wherein: the heating removes the first solvent.

Example 35. The method of Example 28, wherein the solid perovskite layer is characterized by a stress between −50 MPa and 50 MPa, as measured by x-ray diffraction (XRD) at room temperature.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a first layer comprising a perovskite, the first layer having a thickness (t); and
an additive comprising at least one of an aromatic ammonium cation or an alkyl ammonium cation, wherein:
the perovskite comprises a plurality of perovskite grains separated by a plurality of grain boundaries,
a portion of the additive is positioned at or near the grain boundaries or at a surface of the first layer or a combination thereof, and
the first layer is characterized by a stress between −50 MPa and 50 MPa.

2. The device of claim 1, wherein the additive further comprises an anion.

3. The device of claim 2, wherein the anion comprises at least one of a halide, a pseudo halide, formate, carbonate, or nitrate.

4. The device of claim 1, wherein a portion of the additive is positioned at or near the grain boundaries.

5. The device of claim 1, wherein the stress is between −5 MPa and 5 MPa.

6. The device of claim 1, wherein the first layer is further characterized by a strain of between −0.1 and 0.1 (unitless).

7. The device of claim 1, wherein the first layer has a thickness between 100 nm and 20 μm.

8. The device of claim 1, wherein the additive has a length between 5 Å and 75 Å.

9. The device of claim 1, wherein the alkyl group of the alkyl ammonium cation comprises a hydrocarbon group having between 2 and 30 carbon atoms.

10. The device of claim 1, wherein the alkyl ammonium cation comprises n-octyl ammonium.

11. The device of claim 1, wherein the aromatic ammonium cation comprises at least one of benzyl ammonium, methylbenzyl ammonium, or a combination thereof.

12. The device of claim 16, wherein the anion comprises at least one of iodide, chloride, bromide, formate, carbonate, nitrate, thiocyanate, or a combination thereof.

13. The device of claim 1, wherein a portion of the additive is positioned in the first layer at a concentration between greater than 0 mol % and 10 mol %.

14. The device of claim 1, further comprising a second layer, wherein the first layer and the second layer are parallel and adjacent to each other, forming a first interface.

15. The device of claim 20, wherein a portion of the additive is positioned at the first interface.

16. A method comprising:
preparing a solution comprising a perovskite precursor and an additive; and
applying the solution to a surface, creating a liquid layer of the solution, wherein;
the applying results in the forming of a solid perovskite layer comprising a plurality of grains and grain boundaries,
the perovskite layer forms an interface between the surface and the perovskite layer, and
a portion of the additive is positioned within a grain boundary, at the interface, or a combination thereof.

17. The method of claim 16, wherein:
the solution comprises an A-site component (A), a B-site component (B), and an X-site component (X) for synthesizing a target perovskite crystal comprising A, B, and X,
the solution comprises the additive at a molar concentration between greater than 0 mol % and less than 10 mol %, and
the molar concentration is calculated relative to the moles of B added to the solution.

18. The method of claim 17, wherein the molar concentration is between 1 mol % and 5 mol %, inclusively.

19. The method of claim 16, wherein the applying is performed using at least one of spin-coating, blade-coating, curtain-coating, spray-coating, or a combination thereof.

20. The method of claim 16, wherein the solution further comprises a first solvent.
